(19) United States
(12) Patent Application Publication
(10) Pub. No.: US 2018/0219109 A1
(43) Pub. Date: Aug. 2, 2018

(54) SOLAR MODULE AND METHOD FOR MANUFACTURING THE SOLAR MODULE

(71) Applicant: MITSUBISHI ELECTRIC CORPORATION, Tokyo (JP)

(72) Inventor: Yoichiro NISHIMOTO, Tokyo (JP)

(73) Assignee: Mitsubishi Electric Corporation, Tokyo (JP)

(21) Appl. No.: 15/746,657

(22) PCT Filed: Oct. 16, 2015
(86) PCT No.: PCT/JP2015/079369

§ 371 Date: Jan. 22, 2018

(51) Int. Cl. H01L 31/02; H01L 31/0224; H01L 31/18

(52) U.S. Cl. CPC H01L 31/02013; H01L 31/1876; H01L 31/022433; H01L 31/0201

(57) ABSTRACT

A light-receiving-surface bus electrode has a protrusion on an upper surface thereof in an intersection region where the bus electrode intersects with each of light-receiving-surface grid electrodes, the protrusion protruding from the upper surface and having a shape corresponding to a shape of each of the grid electrodes with the bus electrode and each of the grid electrodes overlapping. A light-receiving-surface-side lead wire has a flat upper surface opposite from a lower surface of the lead wire, the lower surface being an attachment surface to the bus electrode. The lead wire also has a recess in the lower surface, the recess being capable of accommodating the protrusion. A bottom surface of the recess and an upper portion of the protrusion are attached together with the protrusion accommodated in the recess, and the lower surface is attached to the upper surface of the bus electrode.

### FIELD

The present invention relates to a solar module having electrodes of individual solar cells interconnected through tab wires, a method for manufacturing the solar module, and a lead wire.

### BACKGROUND

A typical crystalline-silicon solar cell structure has an anti-reflection coating formed on a photoelectric conversion portion having a p-n junction formed therein. Formed on a light-receiving-surface side of the photoelectric conversion portion is a comb-shaped front-surface electrode. On an entire rear surface of the photoelectric conversion portion, a rear-surface electrode is placed. The front-surface electrode and the rear-surface electrode are formed by printing and firing metal pastes thereon. A p-type silicon substrate is usually used as the photoelectric conversion portion, and an n-type dopant diffusion layer is formed on the light-receiving-surface side of the p-type silicon substrate. In forming the rear-surface electrode, an aluminum paste, which contains aluminum, is used to form a p+ layer on the rear surface of the p-type silicon substrate. A silver-containing paste, which achieves contact with the n-type dopant diffusion layer by only printing and firing, is used in forming the front-surface electrode.

The anti-reflection coating of a solar cell plays an important role of passivating the surface of the solar cell, in addition to the role of reducing the reflectance of light at the light receiving surface. Neighboring silicon atoms inside a crystal of the silicon substrate form covalent bonds, thereby establishing stability. However, silicon atoms on the surface of the silicon substrate, which is at the extremity of an array of silicon atoms, have no neighboring atoms with which to form the bonds, displaying unstable energy levels called dangling bonds.

Dangling bonds are electrically active. They thus cause recombination of carriers photogenerated inside the silicon substrate, which provides a factor that lowers the power generation characteristics of the solar cell and thereby produces a loss of the power generation characteristics. The surface of the silicon substrate of a solar cell is terminated in some way to reduce the dangling bonds and thereby inhibit the loss of the power generation characteristics.

It is known that, in a solar cell, dangling bonds are not terminated at the interface where metal and silicon make contact, such as in a region beneath an electrode, thereby increasing the speed of carrier recombination. An electrode is necessary to extract the carriers generated inside the solar cell. The region underneath the electrode, however, causes a significant loss of the power generation characteristics of the solar cell. Hence, there is a demand for a reduction in area of the electrode of a solar cell.

To reduce the loss of the power generation characteristics resulting from the contact between the metal and the silicon in a region beneath the electrode, a solar cell disclosed in, for example, Patent Literature 1 includes a first electrode formed such that an extraction electrode for extracting photogenerated carriers from a silicon substrate is in contact with the silicon substrate, and a second electrode formed such that a collecting electrode for collecting the carriers collected by the first electrode is in contact with the first electrode. The second electrode is in only partial contact with the silicon substrate or is not in contact with the silicon substrate at least outside the contact point between the first electrode and the second electrode. The solar cell in Patent Literature 1 increases its efficiency by allowing only the first electrode to be in contact with the silicon substrate and preventing the second electrode from making contact with the silicon substrate.

### CITATION LIST

### Patent Literature

Patent Literature 1: WO/2012/077568

### SUMMARY

### Technical Problem

The solar cell according to Patent Literature 1 described above uses different pastes for forming the first electrode, which is a grid electrode, and the second electrode, which is a bus electrode, and thus necessitates printing the pastes more than once to form the front-surface electrode. Additionally, the bus electrode has a configuration in which only regions having the grid electrode underneath are elevated.

A grid electrode and a bus electrode are printed usually at the same time. In this case, the bus electrode has a relatively flat surface that can provide a sufficient area for attaching a lead wire during the interconnection with lead wires. The technique in Patent Literature 1, however, forms protrusions and recesses in the surface of the bus electrode, causing the lead wire to be attached to only protrusion portions of the bus electrode. Because of this, a sufficient area cannot be provided for attaching the lead wire to the bus electrode and it becomes highly likely that the lead wire is separated from the bus electrode; thus, the long-term reliability of the solar module may be adversely affected. In cases other than the solar cell in Patent Literature 1, a bus electrode also has a configuration in which only regions having a grid electrode underneath are elevated if the grid electrode and the bus electrode are printed in separate printing processes.

The area for attaching the lead wire to the bus electrode may be increased by, for example, pouring solder into gaps between the lead wire and recess portions of the bus electrode. In general, however, solder that covers the lead wire is melted to connect the lead wire to the bus electrode. When the solder is poured into the gaps between the lead wire and the recess portions of the bus electrode, other problems arise such as a problem of failure of application of a sufficient amount of solder to the surface of the lead wire and a problem of an increase in the amount of solder used.

The present invention has been achieved in view of the above, and an object of the present invention is to provide a solar module having an overlapping region between a grid electrode and a bus electrode and including a lead wire attached to the bus electrode with high long-term reliability.

### Solution to Problem

To solve the problems described above and achieve the object described above, the present invention provides a solar module comprising: a plurality of grid electrodes extending in a predefined direction and placed in parallel with each other on a one surface side of a semiconductor substrate having a photoelectric conversion portion; a bus electrode extending in a direction intersecting with the predefined direction on the one surface side of the semiconductor substrate; and a lead wire extending in the direction intersecting with the predefined direction and placed on and attached to the bus electrode. The bus electrode has a protrusion portion on an upper surface thereof in an intersection region where the bus electrode intersects with each of the grid electrodes, the protrusion portion protruding from the upper surface of the bus electrode and having a shape corresponding to a shape of each of the grid electrodes with the bus electrode and each of grid electrodes overlapping. The lead wire has: an upper surface that is a flat surface and opposite from a lower surface of the lead wire, the lower surface of the lead wire being an attachment surface to the bus electrode; and a recess portion in the lower surface, the recess being capable of accommodating the protrusion portion therein, and a bottom surface of the recess portion and an upper portion of the protrusion portion are attached together with the protrusion portion accommodated in the recess portion, and the lower surface is attached to the upper surface of the bus electrode.

### Advantageous Effects of Invention

The present invention produces an effect of providing a solar module having an overlapping region between a grid electrode and a bus electrode and including the lead wire that is attached to the bus electrode with high long-term reliability.

### BRIEF DESCRIPTION OF DRAWINGS

FIG. 1 is a perspective view of a solar panel according to a first embodiment of the present invention.

FIG. 2 is a perspective view illustrating a solar cell array made by sequentially connecting a plurality of solar cells according to the first embodiment of the present invention using a lead wire, as encased in the solar panel.

FIG. 3 is sectional view of an important portion of the solar panel according to the first embodiment of the present invention, illustrating how two adjacent solar cells are connected together.

FIG. 4 is a perspective view of the plurality of solar cells electrically connected in series in the solar cell array according to the first embodiment of the present invention, as observed from above, i.e., from a light-receiving-surface side.

FIG. 5 is a perspective view of the plurality of solar cells electrically connected in series in the solar cell array according to the first embodiment of the present invention, as observed from below, i.e., from an opposite side of the light-receiving-surface side.

FIG. 6 is a top view of a solar cell according to the first embodiment of the present invention.

FIG. 7 is a rear view of the solar cell according to the first embodiment of the present invention.

FIG. 8 is a top view of the solar cell according to the first embodiment of the present invention with a light-receiving-surface-side lead wire attached to a light-receiving-surface bus electrode of the solar cell, as observed from the light-receiving-surface side.

FIG. 9 is a rear view of the solar cell according to the first embodiment of the present invention with a rear-surface-side lead wire attached to a rear-surface bus electrode of the solar cell, as observed from a rear surface side, which is the opposite side of the light-receiving-surface side.

FIG. 10 is a top view of an important portion of the solar cell according to the first embodiment of the present invention, illustrating a connection portion of a light-receiving-surface grid electrode and the light-receiving-surface bus electrode.

FIG. 11 is a sectional view of an important portion of the solar cell according to the first embodiment of the present invention taken along line XI-XI in FIG. 10, illustrating the connection portion of the light-receiving-surface grid electrode and the light-receiving-surface bus electrode.

FIG. 12 is a top view of an important portion of the light-receiving-surface-side lead wire according to the first embodiment of the present invention.

FIG. 13 is a bottom view of an important portion of the light-receiving-surface-side lead wire according to the first embodiment of the present invention.

FIG. 14 is a sectional view of an important portion of the light-receiving-surface-side lead wire according to the first embodiment of the present invention, taken along line XIV-XIV in FIG. 12.

FIG. 15 is a sectional view of an important portion of the light-receiving-surface-side lead wire according to the first embodiment of the present invention, taken along line XV-XV in FIG. 12.

FIG. 16 is a top view of an important portion of the light-receiving-surface-side lead wire according to the first embodiment of the present invention, illustrating the light-receiving-surface-side lead wire covered with solder.

FIG. 17 is a sectional view of an important portion of the light-receiving-surface-side lead wire according to the first embodiment of the present invention, illustrating the light-receiving-surface-side lead wire attached to the light-receiving-surface bus electrode.

FIG. 18 is a flowchart describing a procedure for a manufacturing method of the solar panel according to the first embodiment of the present invention.

FIG. 19 is an exploded perspective view of the solar panel according to the first embodiment of the present invention, illustrating how components of the solar panel are stacked.

FIG. 20 is a schematic diagram illustrating an exemplary processing device for forming the light-receiving-surface-side lead wire having a surface covered with the solder according to the first embodiment of the present invention.

FIG. 21 is a sectional view of an important portion, illustrating another light-receiving-surface-side lead wire according to the first embodiment of the present invention and corresponding to FIG. 14.

FIG. 22 is a top view of an important portion of a solar cell according to a second embodiment of the present invention, illustrating a connection portion of the light-receiving-surface grid electrode and the light-receiving-surface bus electrode.

FIG. 23 is a sectional view of an important portion of the solar cell according to the second embodiment of the present invention, illustrating the connection portion of the light-receiving-surface grid electrode and the light-receiving-surface bus electrode.

FIG. 24 is a sectional view of an important portion of the solar cell according to the second embodiment of the present invention, illustrating the light-receiving-surface bus electrode.

FIG. 25 is a sectional view of an important portion of the solar cell according to the second embodiment of the present invention, illustrating the connection portion of the light-receiving-surface grid electrode and the light-receiving-surface bus electrode.

FIG. 26 is a top view of an important portion of a light-receiving-surface-side lead wire according to the second embodiment of the present invention.

FIG. 27 is a bottom view of an important portion of the light-receiving-surface-side lead wire according to the second embodiment of the present invention.

FIG. 28 is a sectional view of an important portion of the light-receiving-surface-side lead wire according to the second embodiment of the present invention.

FIG. 29 is a sectional view of an important portion of the light-receiving-surface-side lead wire according to the second embodiment of the present invention.

FIG. 30 is a sectional view of an important portion of the light-receiving-surface-side lead wire according to the second embodiment of the present invention, taken along line XXX-XXX in FIG. 26.

FIG. 31 is a sectional view of an important portion of the light-receiving-surface-side lead wire according to the second embodiment of the present invention, illustrating the light-receiving-surface-side lead wire attached to the light-receiving-surface bus electrode of the solar cell according to the second embodiment, taken along a longitudinal direction of the light-receiving-surface-side lead wire at a position in which the recess portion is formed.

FIG. 32 is a sectional view of an important portion of the light-receiving-surface-side lead wire according to the second embodiment of the present invention, illustrating the light-receiving-surface-side lead wire attached to the light-receiving-surface bus electrode of the solar cell according to the second embodiment, taken along the longitudinal direction of the light-receiving-surface-side lead wire at a position in which the recess portion is not formed.

FIG. 33 is a top view of an important portion of a light-receiving-surface-side lead wire according to a third embodiment of the present invention.

FIG. 34 is a bottom view of an important portion of the light-receiving-surface-side lead wire according to the third embodiment of the present invention.

FIG. 35 is a sectional view of an important portion of the light-receiving-surface-side lead wire according to the third embodiment of the present invention, taken along line XXXV-XXXV in FIG. 33.

FIG. 36 is a sectional view of an important portion of the light-receiving-surface-side lead wire according to the third embodiment of the present invention, taken along line XXXVI-XXXVI in FIG. 33.

FIG. 37 is a sectional view of an important portion of the light-receiving-surface-side lead wire according to the third embodiment of the present invention, taken along line XXXVII-XXXVII in FIG. 33.

FIG. 38 is a sectional view of an important portion of the light-receiving-surface-side lead wire according to the third embodiment of the present invention, illustrating the light-receiving-surface-side lead wire attached to the light-receiving-surface bus electrode illustrated in FIGS. 22 to 25, taken along a longitudinal direction of the light-receiving-surface-side lead wire at a position in which the recess portion is formed.

FIG. 39 is a sectional view of an important portion of the light-receiving-surface-side lead wire according to the third embodiment of the present invention, illustrating the light-receiving-surface-side lead wire attached to the light-receiving-surface bus electrode illustrated in FIGS. 22 to 25, taken along the longitudinal direction of the light-receiving-surface-side lead wire at a position in which the recess portion is not formed.

FIG. 40 is a top view of an important portion of a solar cell according to a fourth embodiment of the present invention, illustrating a connection portion of the light-receiving-surface grid electrode and the light-receiving-surface bus electrode.

FIG. 41 is a sectional view of an important portion of the solar cell according to the fourth embodiment of the present invention taken along line XLI-XLI in FIG. 40, illustrating the connection portion of the light-receiving-surface grid electrode and the light-receiving-surface bus electrode.

FIG. 42 is a sectional view of an important portion of the light-receiving-surface bus electrode according to the fourth embodiment of the present invention, illustrating the light-receiving-surface-side lead wire attached to the light-receiving-surface bus electrode.

### DESCRIPTION OF EMBODIMENTS

Exemplary embodiments of a solar module according to the present invention, a method for manufacturing the solar module, and a lead wire are described below in detail with reference to the drawings. The present invention is not limited to the embodiments and can be modified as appropriate in a scope not departing from the spirit of the present invention. To facilitate understanding, the scales of components in the drawings described below may differ from those of actual components. This is similarly applicable to the scales of the drawings.

### First Embodiment

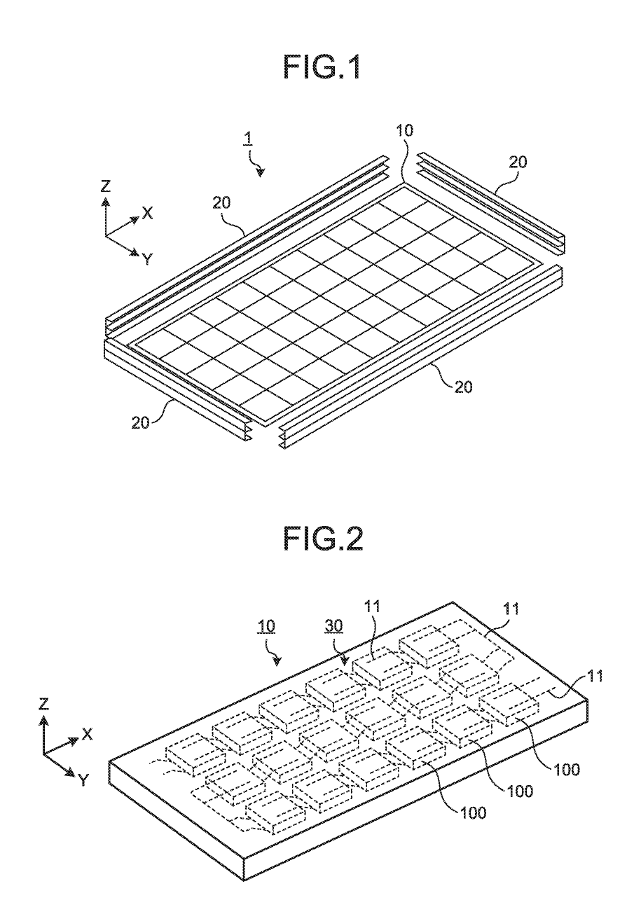

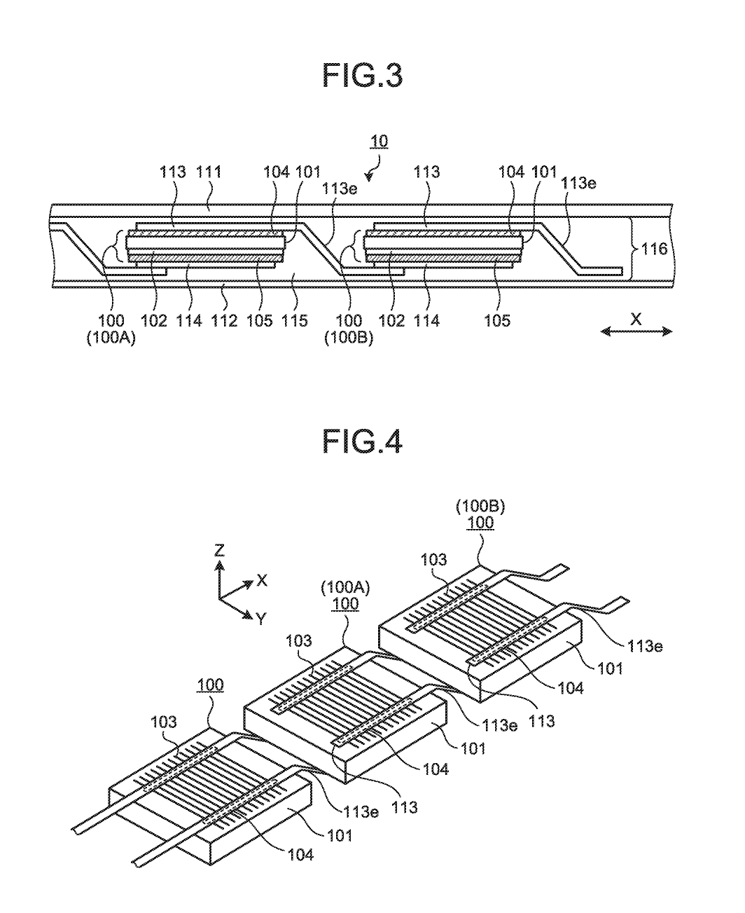

FIG. 1 is a perspective view of a solar panel 1 according to a first embodiment of the present invention. FIG. 1 illustrates the solar panel 1 as dismantled into components that configure the solar panel 1, namely a solar module 10 and a frame member 20 for surrounding an outer edge portion of the solar module 10 along the entire perimeter of the solar module 10. FIG. 2 is a perspective view illustrating a solar cell array 30 made by sequentially connecting a plurality of solar cells 100 according to the first embodiment of the present invention using a lead wire 11, as encased in the solar panel 1. FIG. 3 is sectional view of an important portion of the solar panel 1 according to the first embodiment of the present invention, illustrating how two adjacent solar cells 100 are connected together. FIG. 3 illustrates a section along a predefined first direction that is a direction in which the solar cells 100 are connected together, that is, an X direction.

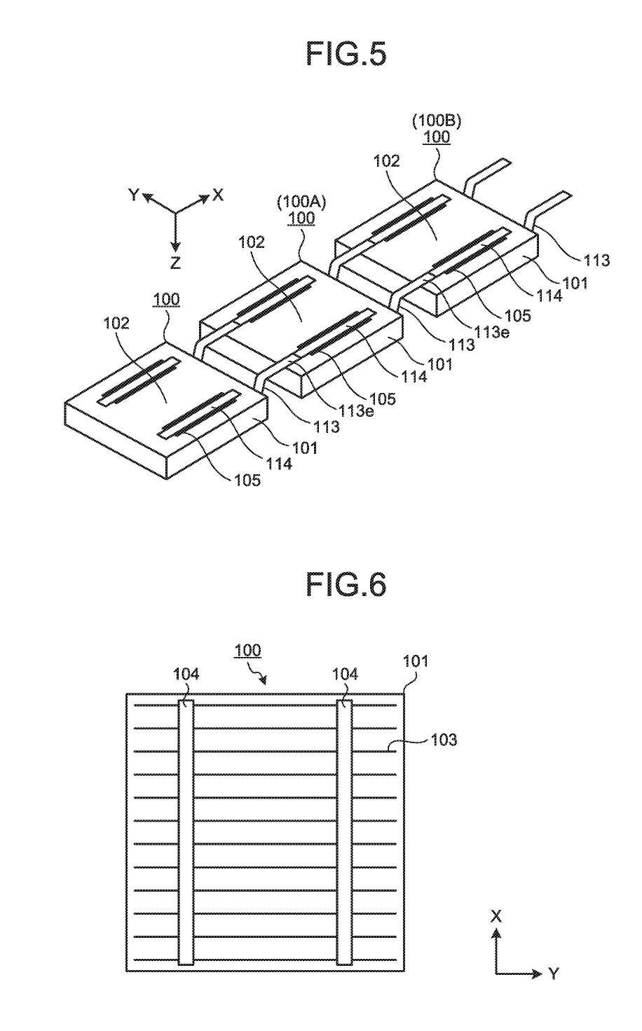

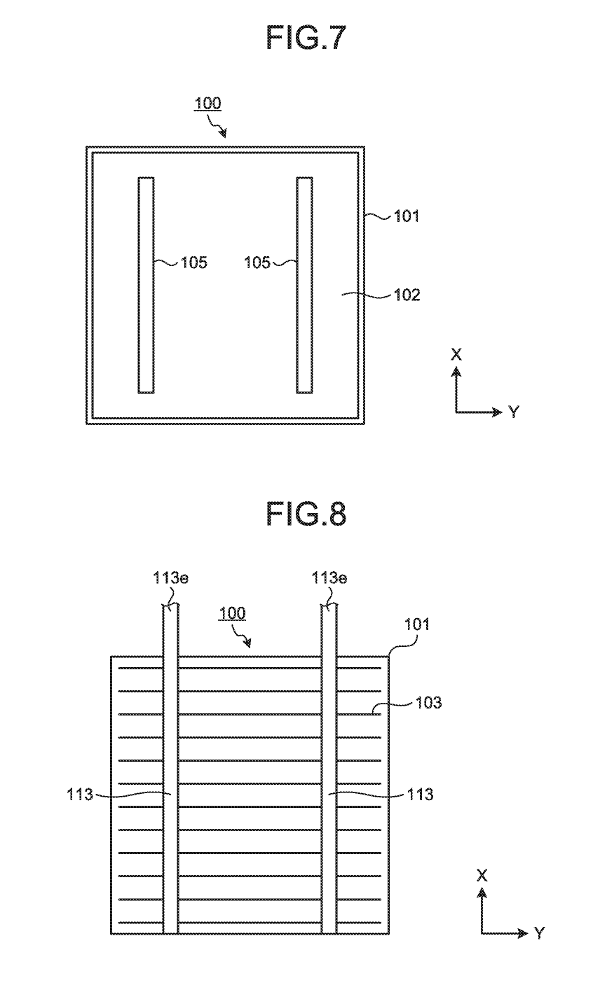

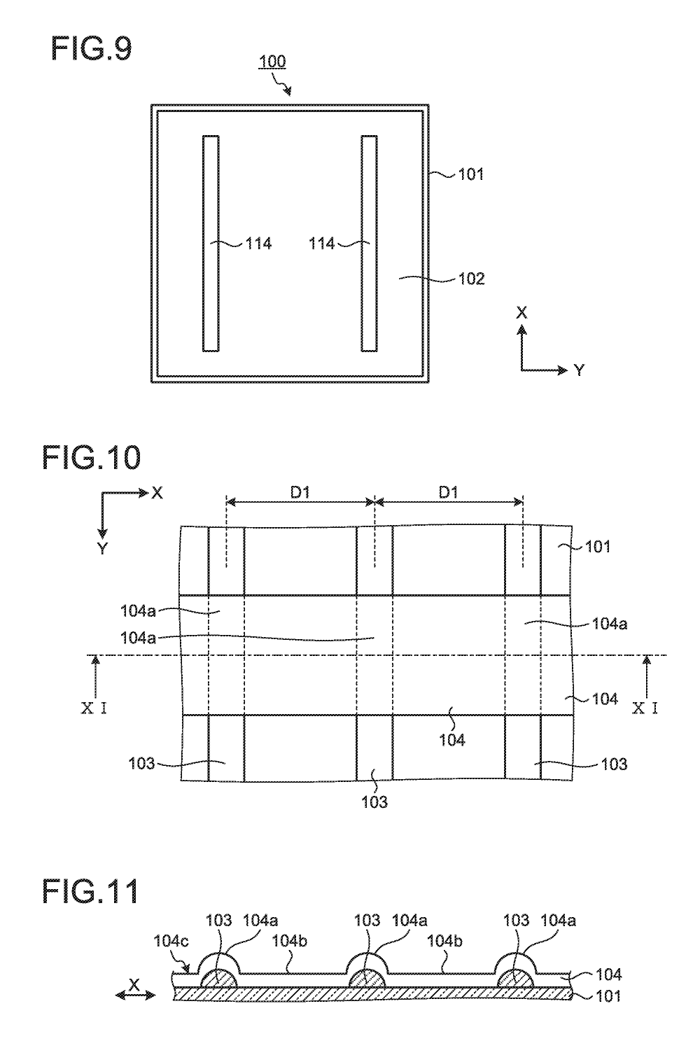

FIG. 4 is a perspective view of a plurality of solar cells 100 electrically connected in series in the solar cell array 30 according to the first embodiment of the present invention, as observed from above, i.e., from a light-receiving-surface side. FIG. 5 is a perspective view of the plurality of solar cells 100 electrically connected in series in the solar cell array 30 according to the first embodiment of the present invention, as observed from below, i.e., from an opposite side of the light-receiving-surface side. FIG. 6 is a top view of the solar cell 100 according to the first embodiment of the present invention. FIG. 7 is a rear view of the solar cell 100 according to the first embodiment of the present invention. FIG. 8 is a top view of the solar cell 100 according to the first embodiment of the present invention with a light-receiving-surface-side lead wire 113 attached to a light-receiving-surface bus electrode 104 of the solar cell 100, as observed from the light-receiving-surface side. FIG. 9 is a rear view of the solar cell 100 according to the first embodiment of the present invention with a rear-surface-side lead wire 114 attached to a rear-surface bus electrode 105 of the solar cell 100, as observed from a rear surface side, which is the opposite side of the light-receiving-surface side.

As illustrated in FIG. 1, the solar panel 1 includes the solar module 10, which has a flat-plate-like shape, and the frame member 20 for surrounding the outer edge portion of the solar module 10 along the entire perimeter of the solar module 10. As illustrated in FIGS. 2 and 3, the solar module 10 is configured by encasing in resin the plurality of solar cells 100 arranged in a length direction and a width direction that are orthogonal to each other on an identical plane, by covering the light-receiving-surface side of the encased solar cells 100 with a light transmitting front-surface covering material 111, such as glass, and by covering the rear surface side or a non-light-receiving-surface side of the encased solar cells 100 with a rear-surface covering material 112.

The frame member 20 is fabricated by extrusion of a metal material, such as aluminum, and has a U-shaped portion that has a section perpendicular to its longitudinal direction in a U-like shape and covers the outer edge portion of the solar module 10 along the entire perimeter of the solar module 10 as illustrated in FIG. 1. The frame member 20 is fixed to the solar panel 1 using a butyl sealing medium or a silicon adhesive agent and plays roles of reinforcing the solar panel 1 and attaching the solar panel 1 to a mount placed on a building such as a house or a concrete building, on the ground, or on a structure.

As illustrated in FIG. 3, the solar panel 1 has a multilayer configuration that includes, from the light-receiving-surface side, the light transmitting front-surface covering material 111, such as a glass substrate, a cell arrangement layer 116 in which the solar cell array 30 is encased in resin 115, such as ethylene-vinyl acetate (EVA), and the rear-surface covering material 112, which has good weatherability and made of, for example, polyethylene terephthalate (PET), polyvinyl fluoride (PVF). As illustrated in FIGS. 3 to 5, the solar cell array 30 is configured by sequentially connecting the plurality of solar cells 100 electrically in series using the light-receiving-surface-side lead wire 113 and the rear-surface-side lead wire 114.

The solar cell 100 is configured in a manner described below, using a piece of p-type silicon having a thickness of approximately 150 μm to 300 μm as a substrate serving as, for example, a p-type dopant diffusion layer. The silicon substrate is made in many cases using a monocrystalline silicon substrate, which achieves high photoelectric conversion efficiency. In the solar cell 100, an n-type diffusion layer, which is an undepicted n-type dopant diffusion layer, is formed by phosphorus diffusion on a one surface side of a p-type monocrystalline silicon substrate 101, which is a p-type layer that is the p-type dopant diffusion layer. The p-type monocrystalline silicon substrate 101 and the n-type diffusion layer configure a photoelectric conversion portion that performs photoelectric conversion to thereby generate power. An undepicted anti-reflection coating made of a silicon nitride coating for preventing reflection of incoming light and improving the photoelectric conversion efficiency is placed on the n-type diffusion layer by surface treatment to serve as a light receiving surface of the solar cell 100. An undepicted p+ layer including a highly-concentrated dopant is formed on the rear surface side of the p-type monocrystalline silicon substrate 101, and a rear-surface collecting electrode 102 made of aluminum for the purpose of reflecting incoming light and extracting electric power is also placed on a substantially entire rear surface of the p-type monocrystalline silicon substrate 101. Reference to the p-type monocrystalline silicon substrate 101 in the drawings below may include the n-type diffusion layer and the p+ layer.

As illustrated in FIGS. 3, 4, and 6, a grid electrode and a bus electrode that serve as a light-receiving-surface-side electrode for extracting electric energy resulting from the conversion of incoming light are placed on the light receiving surface of the p-type monocrystalline silicon substrate 101. That is, a light-receiving-surface grid electrode 103, which is a thin wire electrode made using silver, and the light-receiving-surface bus electrode 104 of predetermined width, which is also made using silver and is an electrode for connection to a light-receiving-surface lead, are formed on the light receiving surface of the p-type monocrystalline silicon substrate 101, and respective bottom surface portions of the light-receiving-surface grid electrode 103 and the light-receiving-surface bus electrode 104 are electrically connected to the n-type diffusion layer described above. The light-receiving-surface grid electrode 103 is omitted in FIG. 3 for reasons of illustration.

Two light-receiving-surface bus electrodes 104 are formed parallel with each other along the first direction, which is the direction in which the solar cells 100 are connected together, that is, the X direction. A plurality of light-receiving-surface grid electrodes 103 is placed in a parallel and elongated fine pattern along a second direction, that is, a Y direction. Here, the second direction is a direction that intersects with the light-receiving-surface bus electrodes 104 at an angle of 90 degrees. The light-receiving-surface grid electrodes 103 are placed with a predefined light-receiving-surface-grid-electrode placement spacing D1 in their width directions. The light-receiving-surface-grid-electrode placement spacing D1 is hereinafter referred to as the placement spacing D1. The placement spacing D1 is a distance between the middle points of light-receiving-surface grid electrodes 103 in their width directions, the light-receiving-surface grid electrodes 103 being located next to each other in their width directions, that is, in the first direction.

The light-receiving-surface grid electrodes 103 are formed so as to be as thin as possible and spread over the entire area of the light receiving surface, which is a front surface, in order to extract the electric power generated at the light receiving surface without waste. Upon application of sunlight, the electrodes on the light-receiving-surface side illustrated in FIG. 6 serve as negative electrodes and the electrodes on the rear surface side illustrated in FIG. 7 serve as positive electrodes. Note that the angle at which the second direction intersects with the first direction, that is, the angle at which the light-receiving-surface grid electrodes 103 intersect with the light-receiving-surface bus electrodes 104, is not limited to 90 degrees.

As illustrated in FIGS. 3 and 4, each of the light-receiving-surface bus electrodes 104 is connected to a light-receiving-surface-side lead wire 113 to extract the electric energy collected by the light-receiving-surface grid electrodes 103 further to the outside. The light-receiving-surface bus electrodes 104 are illustrated in FIG. 4 as being narrower than the light-receiving-surface-side lead wires 113 to clearly describe how the light-receiving-surface bus electrode 104 and the light-receiving-surface-side lead wires 113 overlap each other; however, in practice, the light-receiving-surface bus electrodes 104 may have the same widths as those of the light-receiving-surface-side lead wires 113 or somewhat wider widths than those of the light-receiving-surface-side lead wires 113.

As illustrated in FIGS. 3, 5, and 7, the rear-surface collecting electrode 102, which is made of aluminum, is placed on the rear surface of the p-type monocrystalline silicon substrate 101 so as to cover the substantially entire rear surface. The rear-surface bus electrodes 105, which are each an electrode for connection to a rear surface lead and made of silver, extend in the first direction, which is the direction in which the solar cells 100 are connected together, on the rear surface of the p-type monocrystalline silicon substrate 101 at positions corresponding to those of the light-receiving-surface bus electrodes 104, that is, at positions in which the rear-surface bus electrodes 105 overlap the light-receiving-surface bus electrodes 104 in a plane direction of the p-type monocrystalline silicon substrate 101. The rear-surface collecting electrode 102 and the rear-surface bus electrodes 105 configure a rear-surface-side electrode. As illustrated in FIGS. 3 and 5, each of the rear-surface bus electrodes 105 is connected to the rear-surface-side lead wire 114 to extract the electric energy collected by the rear-surface collecting electrode 102 further to the outside. The rear-surface bus electrodes 105 are placed in a form of discrete dots or stepping stones in some cases, in place of the form of a straight line as illustrated in the first embodiment.

In the solar cell 100 configured in this manner, when sunlight shines from the light-receiving-surface side of the solar cell 100, that is, the side of the solar cell 100 on which the anti-reflection coating is formed, and reaches the attachment surface between the p-type layer and the n-type diffusion layer, which is an internal p-n junction, holes and electrons having charges are separated from the bonds at the p-n junction. The separated electrons move toward the n-type diffusion layer. When the electrons reach the n-type diffusion layer, they are collected by the light-receiving-surface grid electrodes 103. The separated holes move toward the p+ layer. When the holes reach the p+ layer of the p-type monocrystalline silicon substrate 101, they are collected by the rear-surface collecting electrode 102. In this manner, a potential difference is caused between the n-type diffusion layer and the p+ layer with the p+ layer having the higher potential. As a result, current flows to an undepicted external circuit when it is connected, with the light-receiving-surface-side electrode, which is connected to the n-type diffusion layer, serving as a negative pole and the rear-surface-side electrode, which is connected to the p+ layer, serving as a positive pole, and thereby the operation of a solar cell is exhibited. Although the output voltage of one solar cell is small, the plurality of solar cells 100 can be electrically connected together in series or in parallel in the solar module 10, so that the voltage is increased to a usable level.

As illustrated in FIGS. 3 to 5, the plurality of solar cells 100 are connected together in series in the X direction in the drawings, which is the first direction, by using the light-receiving-surface-side lead wires 113 and the rear-surface-side lead wires 114. The first direction is the direction in which the solar cells 100 are connected together and the light-receiving-surface bus electrodes 104 and the rear-surface bus electrodes 105 extend. Some of the solar cells 100 may be connected together in the Y direction at an edge portion of the solar cell array 30. A belt-shaped flat-plate copper wire that solder is supplied to, in other words, that is covered or coated with solder, and that is generally referred to as a tab wire is used as the light-receiving-surface-side lead wires 113 and the rear-surface-side lead wires 114.

That is, as illustrated in FIGS. 3 to 5, in the plurality of solar cells 100 arranged in the first direction, the solar cells 100 are connected together in series by electrically connecting the light-receiving-surface bus electrodes 104 on a first solar cell 100A, which is a first solar cell 100, to the rear-surface bus electrodes 105 on a second solar cell 100B, which is a second solar cell 100 located next to the first solar cell 100A, by using the light-receiving-surface-side lead wires 113 and the rear-surface-side lead wires 114, which are belt-shaped lead wires 11.

In the first embodiment, the lead wire 11 is segmented into the light-receiving-surface-side lead wire 113 and the rear-surface-side lead wire 114. Of these two wires, the light-receiving-surface-side lead wire 113 is placed on the light-receiving-surface bus electrode 104, extends in the X direction in the drawing, which is the first direction, and is soldered to the light-receiving-surface bus electrode 104 so as to be connected to the light-receiving-surface bus electrode 104 mechanically and electrically, as illustrated in FIG. 4. As illustrated in FIGS. 4, 5, and 8, the light-receiving-surface-side lead wire 113 has an extension portion 113e so as to have a length greater than that of the solar cell 100 and, when the light-receiving-surface-side lead wire 113 is soldered to the light-receiving-surface bus electrode 104, the extension portion 113e protrudes from the solar cell 100 on one end side.

The rear-surface-side lead wire 114 is placed on the rear-surface bus electrode 105, extends in the X direction in the drawings, which is the first direction, and is soldered to the rear-surface bus electrode 105 so as to be connected to the rear-surface bus electrode 105 mechanically and electrically. To connect the first solar cell 100A, which is the first solar cell 100, to the second solar cell 100B, which is the second solar cell 100, in series electrically, the light-receiving-surface-side lead wires 113 on the first solar cell 100A, which is the first solar cell 100, are soldered to the rear-surface-side lead wires 114 on the second solar cell 100B, which is the second solar cell 100. That is, extension portions 113e of the light-receiving-surface-side lead wires 113 on the first solar cell 100A, which is the first solar cell 100, are placed on the rear surface side of the second solar cell 100B, which is the adjacent second solar cell 100, and soldered to the rear-surface-side lead wires 114, which are soldered to the rear-surface bus electrodes 105.

While only the connection between two neighboring cells, namely the first solar cell 100A and the second solar cell 100B, has been described, similar connections are repeated to connect the plurality of solar cells 100 together in series electrically. While the lead wire 11 is segmented into the light-receiving-surface-side lead wire 113 and the rear-surface-side lead wire 114 in the first embodiment as described above, one continuous lead wire may be used.

In the solar cell 100 according to the first embodiment, the light-receiving-surface grid electrode 103 and the light-receiving-surface bus electrode 104 are paste electrodes formed by printing and firing metal pastes containing silver as described below. During the printing of the metal pastes, the metal paste for forming the light-receiving-surface grid electrodes 103 is printed, and, then, the metal paste for forming the light-receiving-surface bus electrodes 104 is printed. To form the electrical connection between the light-receiving-surface grid electrodes 103 and the light-receiving-surface bus electrodes 104, the metal paste for forming the light-receiving-surface bus electrodes 104 is printed so as to partially cover the metal paste for forming the light-receiving-surface grid electrodes 103. That is, the light-receiving-surface grid electrodes 103 continuously extend in the Y direction in the drawings, which is the second direction, on regions underneath the light-receiving-surface bus electrodes 104.

Because of this, as illustrated in FIGS. 10 and 11, an upper surface 104c of the light-receiving-surface bus electrode 104 has a flat surface 104b and a protrusion portion 104a that is elevated due to the light-receiving-surface bus electrode 104 being placed on the light-receiving-surface grid electrode 103 to protrude from the upper surface 104c. The protrusion portion 104a is formed continuously in the width direction of the light-receiving-surface bus electrode 104 along the entire width. Flat surfaces 104b correspond to all regions of the upper surface 104c of the light-receiving-surface bus electrode 104 where the protrusion portion 104a is not formed.

FIG. 10 is a top view of an important portion of the solar cell 100 according to the first embodiment of the present invention, illustrating a connection portion of the light-receiving-surface grid electrode 103 and the light-receiving-surface bus electrode 104. The connection portion is an intersection region in which the light-receiving-surface grid electrode 103 intersects with the light-receiving-surface bus electrode 104. FIG. 11 is a sectional view of an important portion of the solar cell 100 according to the first embodiment of the present invention taken along line XI-XI in FIG. 10, illustrating the connection portion of the light-receiving-surface grid electrode 103 and the light-receiving-surface bus electrode 104. The light-receiving-surface grid electrode 103 has a semicircle-shaped section perpendicular to its longitudinal direction. The shape of the section of the light-receiving-surface grid electrode 103 perpendicular to the longitudinal direction is not limited to the semicircular shape.

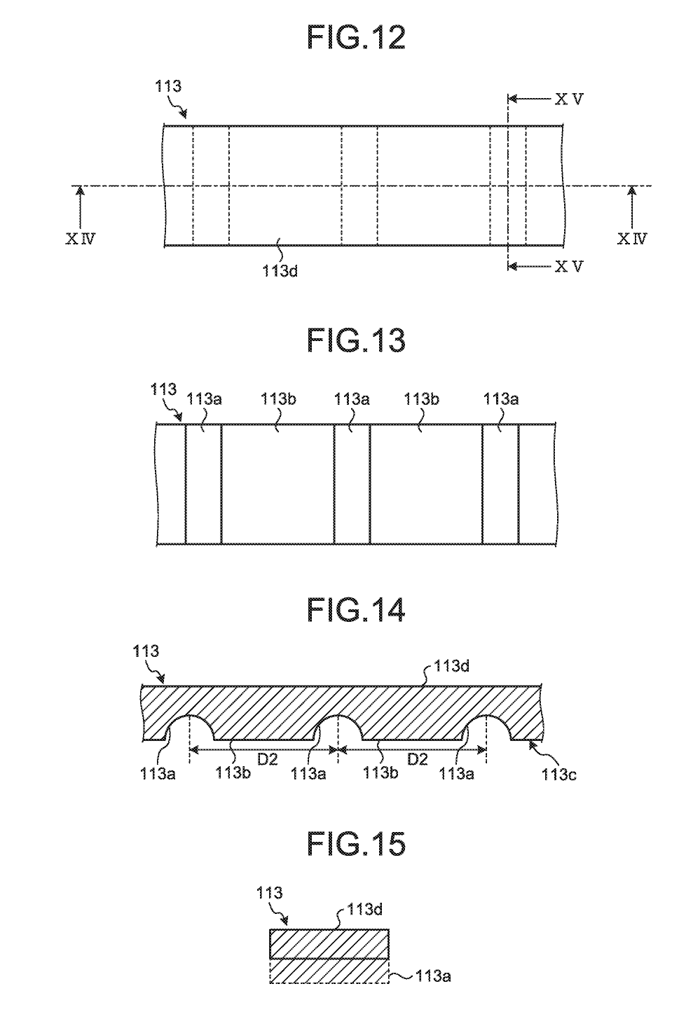

As illustrated in FIGS. 12 to 15, the light-receiving-surface-side lead wire 113 has a lower surface 113c that is an attachment surface to the light-receiving-surface bus electrode 104, and the lower surface 113c has a recess portion 113a that has a shape corresponding to that of the protrusion portion 104a and extends in the width direction of the light-receiving-surface-side lead wire 113, and a flat surface 113b. That is, the light-receiving-surface-side lead wire 113 has recess portions 113a that are formed in the lower surface 113c and have shapes corresponding to the uneven shape of the light-receiving-surface bus electrode 104. FIG. 12 is a top view of an important portion of the light-receiving-surface-side lead wire 113 according to the first embodiment of the present invention. FIG. 13 is a bottom view of an important portion of the light-receiving-surface-side lead wire 113 according to the first embodiment of the present invention. FIG. 14 is a sectional view of an important portion of the light-receiving-surface-side lead wire 113 according to the first embodiment of the present invention, taken along line XIV-XIV in FIG. 12. FIG. 15 is a sectional view of an important portion of the light-receiving-surface-side lead wire 113 according to the first embodiment of the present invention, taken along line XV-XV in FIG. 12.

The longitudinal direction of the light-receiving-surface-side lead wire 113 corresponds to the first direction, that is, the X direction. Flat surfaces 113b correspond to all regions of the lower surface of the light-receiving-surface-side lead wire 113 where the recess portion 113a is not formed. The recess portions 113a are formed in elongated and slender shapes in the width direction of the light-receiving-surface-side lead wire 113 along the entire width. The recess portions 113a are also placed with a predefined recess-portion placement spacing D2 in the longitudinal direction of the light-receiving-surface-side lead wire 113. The recess-portion placement spacing D2 is hereinafter referred to as the placement spacing D2. The placement spacing D2 is a distance between the middle points of recess portions 113a in their width directions, the recess portions 113a being located next to each other in the longitudinal direction of the light-receiving-surface-side lead wire 113. The placement spacing D2 of the recess portions 113a is equal to the placement spacing D1.

The light-receiving-surface-side lead wire 113 has an upper surface 113d that is a flat surface and opposite from the lower surface 113c. The material of the light-receiving-surface-side lead wire 113 is preferably copper, which has the mechanical strength for forming the recess portions 113a and good workability and is inexpensive.

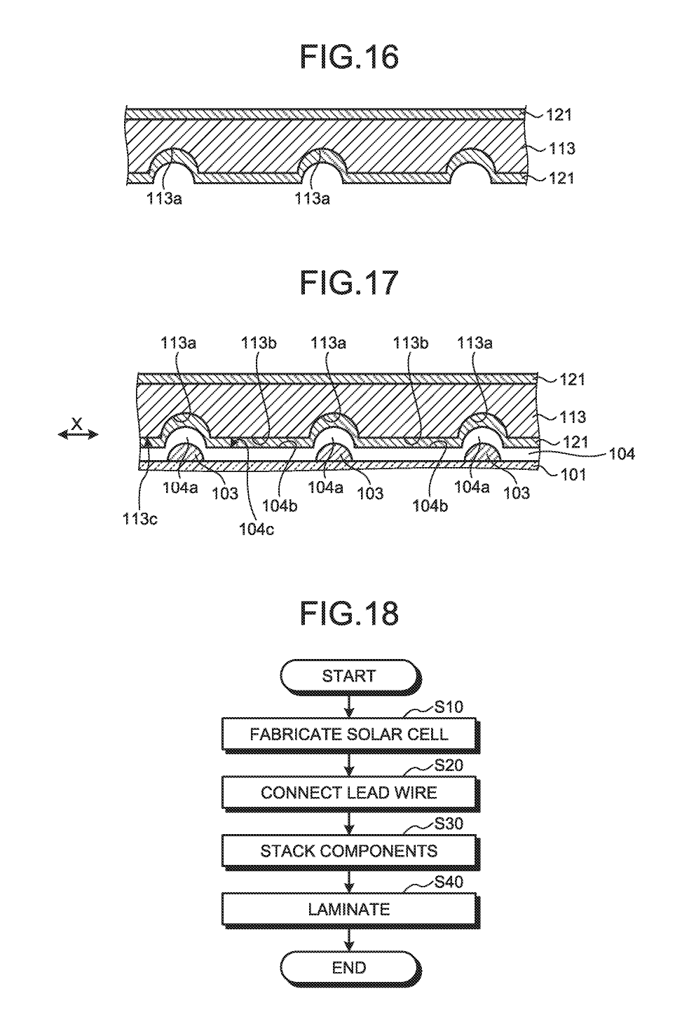

The light-receiving-surface-side lead wire 113 configured as described above is covered with solder 121 in use as illustrated in FIG. 16. FIG. 16 is a top view of an important portion of the light-receiving-surface-side lead wire 113 according to the first embodiment of the present invention, illustrating the light-receiving-surface-side lead wire 113 covered with the solder 121.

FIG. 17 is a sectional view of an important portion of the light-receiving-surface-side lead wire 113 according to the first embodiment of the present invention, illustrating the light-receiving-surface-side lead wire 113 attached to the light-receiving-surface bus electrode 104. As illustrated in FIG. 17, the light-receiving-surface-side lead wire 113 is placed on the light-receiving-surface bus electrode 104 and attached through the solder 121 to the light-receiving-surface bus electrode 104 with the protrusion portions 104a of the light-receiving-surface bus electrode 104 accommodated in the recess portions 113a of the light-receiving-surface-side lead wire 113. That is, the protrusion portions 104a of the light-receiving-surface bus electrode 104 are attached to the recess portions 113a via the solder 121 with no gap therebetween, with the protrusion portions 104a fitted in the recess portions 113a in the lower surface 113c of the light-receiving-surface-side lead wire 113. The flat surfaces 104b of the light-receiving-surface bus electrode 104 are also attached to the flat surfaces 113b of the lower surface 113c of the light-receiving-surface-side lead wire 113 via the solder 121 with no gap therebetween.

In this manner, in the solar module 10, the protrusion portions 104a and the flat surfaces 104b of the light-receiving-surface bus electrodes 104 are attached entirely to the lower surfaces 113c of the light-receiving-surface-side lead wires 113. That is, the solar module 10 maintains a large area for connecting the light-receiving-surface bus electrodes 104 and the light-receiving-surface-side lead wires 113 together and thereby provides high attachment strength between the light-receiving-surface bus electrodes 104 and the light-receiving-surface-side lead wires 113. Hence, in the solar module 10, the light-receiving-surface bus electrodes 104 and the light-receiving-surface-side lead wires 113 are not likely to be separated from each other and are thus not likely to have disconnection, thereby enhancing the reliability of electrical attachment. Accordingly, the solar module 10 achieves a solar module including the light-receiving-surface bus electrodes 104 and the light-receiving-surface-side lead wires 113 that are electrically attached together with high long-term reliability.

Additionally, by reducing the thicknesses of bottom portions of the recess portions 113a in the light-receiving-surface-side lead wires 113, the thicknesses of the light-receiving-surface-side lead wires 113 can be reduced and thereby the thickness of the solar module 10 can be reduced. A portion of the light-receiving-surface-side lead wire 113 where the flat surface 113b is located has a thickness of a dimension that is the sum of the depth of the recess portion 113a and the thickness of the bottom portion of the recess portion 113a. The light-receiving-surface-side lead wire 113 thus maintains a larger sectional area in a thickness direction than a light-receiving-surface-side lead wire 113 having a uniform thickness in its entirety in the plane direction, that is, a light-receiving-surface-side lead wire 113 whose thickness corresponds to the thickness of the bottom portions of the recess portions 113a; thus, the light-receiving-surface-side lead wire 113 achieves a sufficient reduction in electric resistance and provides high rigidity.

Although a relatively simple electrode pattern achieved by the combination of the light-receiving-surface grid electrodes 103 and the light-receiving-surface bus electrodes 104 as illustrated in FIG. 10 has been described as an example, the electrode pattern is not limited thereto. The effects described above can be obtained by: providing the recess portion 113a in the lower surface 113c of the light-receiving-surface-side lead wire 113 such that the recess portion 113a has a shape that corresponds to the shape of the protrusion portion 104a generated on the upper surface 104c due to the light-receiving-surface grid electrode 103 being located underneath the light-receiving-surface bus electrode 104 and that the recess portion 113a can accommodate the protrusion portion 104a and be attached to the protrusion portion 104a; and by placing the light-receiving-surface-side lead wire 113 on the light-receiving-surface bus electrode 104 such that the protrusion portion 104a is fitted in the recess portion 113a.

The protrusion portion 104a of the light-receiving-surface bus electrode 104 and the recess portion 113a of the light-receiving-surface-side lead wire 113 are attached together through the solder 121 with the protrusion portion 104a accommodated in the recess portion 113a. Thus, the recess portion 113a has an inner surface has a shape corresponding to that of the protrusion portion 104a and has a dimension larger than the outer surface dimension of the protrusion portion 104a by, for example, about 30 μm to approximately account for the thickness of the solder 121 to be used for the attachment.

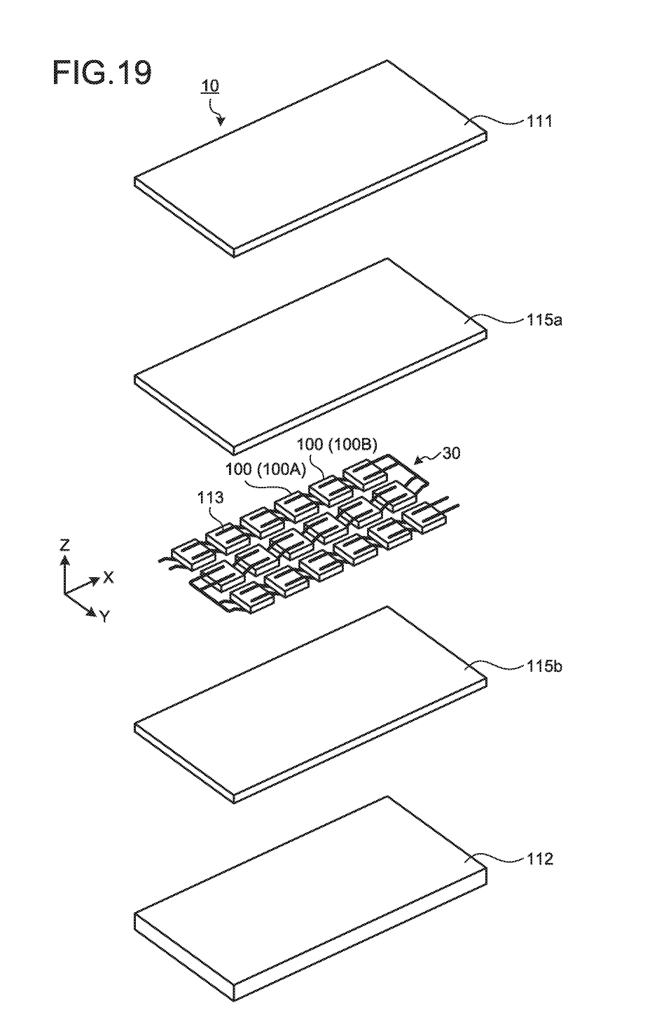

A manufacturing method of the solar panel 1 configured as described above is described next. FIG. 18 is a flowchart describing a procedure for a manufacturing method of the solar panel 1 according to the first embodiment of the present invention. FIG. 19 is an exploded perspective view of the solar panel 1 according to the first embodiment of the present invention, illustrating how the components of the solar panel 1 are stacked. A process to be described below is similar to a manufacturing process of a general solar panel using a silicon substrate, except for the method of connecting the light-receiving-surface-side lead wire 113 to the light-receiving-surface bus electrode 104.

A plurality of solar cells 100 is fabricated in step S10. The p-type monocrystalline silicon substrate 101 is placed in a thermal oxidation furnace and heated in the presence of a phosphorus oxychloride (POCl₃) vapor. A phosphorus glass layer is formed on a surface of the p-type monocrystalline silicon substrate 101 in this manner, and phosphorus is diffused from the phosphorus glass layer into the p-type monocrystalline silicon substrate 101 to form the n-type diffusion layer in a surface layer of the p-type monocrystalline silicon substrate 101.

The phosphorus glass layer is then removed from the surface layer of the p-type monocrystalline silicon substrate 101 in a fluorinated acid solution. A silicon nitride coating (SiN coating) is then formed by a plasma CVD technique as the anti-reflection coating over the n-type diffusion layer except regions for forming the light-receiving-surface side electrodes. The thickness and refractive index of the anti-reflection coating are set to values that inhibit light reflection the most. The anti-reflection coating may be formed by stacking two or more coatings having different refractive indices. The anti-reflection coating may be formed by a different forming method, such as a sputtering technique.

Subsequently, a silver paste including silver is printed by screen printing on the light receiving surface of the p-type monocrystalline silicon substrate 101 in the shapes of the light-receiving-surface grid electrodes 103. The silver paste is then printed by screen printing on the light receiving surface of the p-type monocrystalline silicon substrate 101 in the shapes of the light-receiving-surface bus electrodes 104. Here, the light-receiving-surface grid electrodes 103 are printed in a direction parallel with two opposite edges of the four edges of a square shape of the p-type monocrystalline silicon substrate 101 in a substrate plane direction of the p-type monocrystalline silicon substrate 101. The light-receiving-surface bus electrodes 104 are printed in a direction parallel with the other two opposite edges of the four edges of the square shape of the p-type monocrystalline silicon substrate 101.

An aluminum paste containing aluminum is printed by screen printing on the substantially entire rear surface of the p-type monocrystalline silicon substrate 101. Then, a silver paste including silver is printed by screen printing on the printed aluminum paste in the shapes of the rear-surface bus electrodes 105. The p-type monocrystalline silicon substrate 101 is subjected to a firing process to form the light-receiving-surface grid electrodes 103, the light-receiving-surface bus electrodes 104, the rear-surface collecting electrode 102, and the rear-surface bus electrodes 105. In the manner described above, the solar cells 100 are fabricated.

Subsequently, the lead wires 11 are connected in step S20 to the solar cell 100. First, the light-receiving-surface-side lead wires 113, which are covered with the solder 121, are placed on the light-receiving-surface bus electrodes 104. The rear-surface-side lead wires 114, which are covered with the solder 121, are also placed on the rear-surface bus electrodes 105.

Here, each of the light-receiving-surface-side lead wires 113 is placed on one of the light-receiving-surface bus electrodes 104 with the lower surface 113c of each of the light-receiving-surface-side lead wires 113 facing the upper surface 104c of the corresponding one of the light-receiving-surface bus electrodes 104. Additionally, when each of the light-receiving-surface-side lead wires 113 is placed on the corresponding one of the light-receiving-surface bus electrodes 104, the positions of the protrusion portions 104a of each of the light-receiving-surface bus electrodes 104 are aligned with those of the recess portions 113a of the corresponding one of the light-receiving-surface-side lead wires 113. In this manner, the protrusion portions 104a of each of the light-receiving-surface bus electrodes 104 are accommodated in the recess portions 113a of the corresponding one of the light-receiving-surface-side lead wire 113. The flat surfaces 104b of each of the light-receiving-surface bus electrodes 104 face the flat surfaces 113b of the corresponding one of the light-receiving-surface-side lead wires 113.

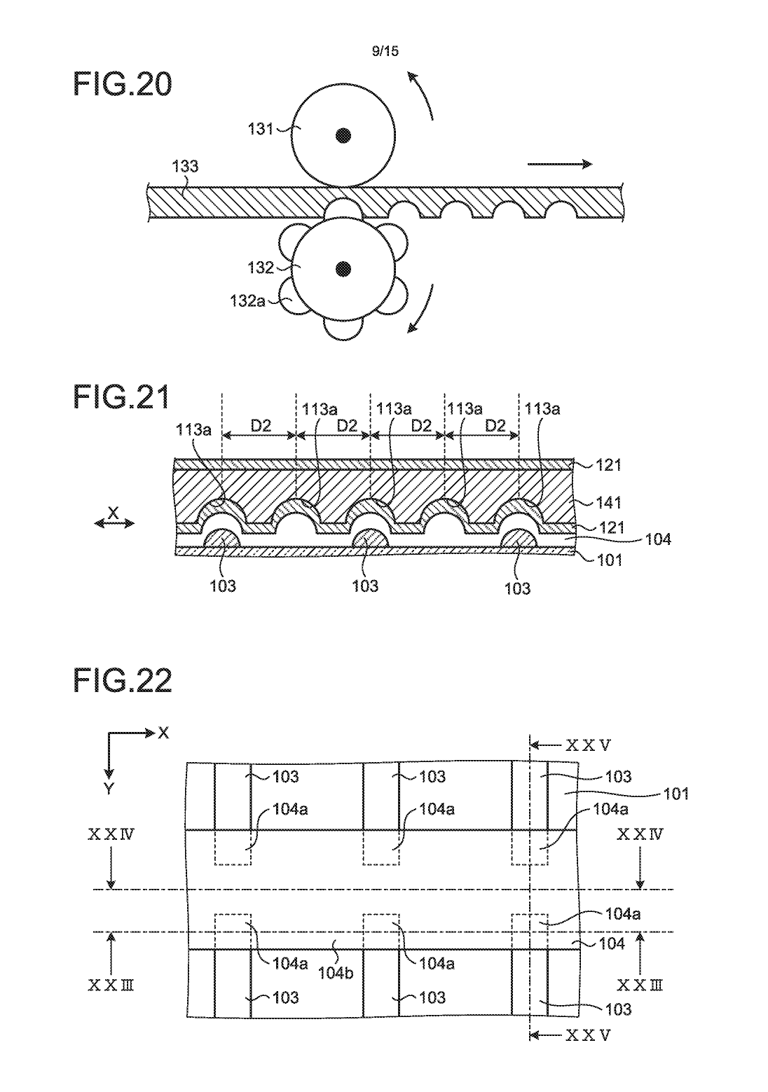

For the interconnection of the light-receiving-surface-side lead wire 113 and the light-receiving-surface bus electrode 104, a flat-plate copper wire 133, which is covered with the solder 121, is supplied from a reel, straightened to remove a curl by straightening means, such a roller device, and, then, cut and placed on the light-receiving-surface bus electrode 104. By providing a processing process that uses an upper roller 131 and a lower roller 132 as illustrated in FIG. 20 between the straightening process of a curl and a placement process on the light-receiving-surface-side lead wire 113, the light-receiving-surface bus electrode 104 having a surface covered with the solder 121 can be formed with ease. FIG. 20 is a schematic diagram illustrating an exemplary processing device for forming the light-receiving-surface-side lead wire 113 having a surface covered with the solder 121 according to the first embodiment of the present invention.

The upper roller 131 is a cylindrical roller with no protrusions on its surface. The lower roller 132 is a roller having protrusions 132a on its surface that corresponds to the recess portions 113a. By causing the flat-plate copper wire 133 covered with solder to pass between the upper roller 131 and the lower roller 132, a lead wire including the light-receiving-surface-side lead wire 113 having the recess portions 113a formed therein and having a surface covered with the solder 121 can be formed with ease. In place of a roller, a press plate may be used to form the recess portions 113a in a flat-plate copper wire. The processing to form the recess portions 113a on the flat-plate copper wire 133 may be performed any time as long as it is performed before the light-receiving-surface-side lead wire 113 is placed on the light-receiving-surface bus electrode 104.

Since the processing to form the recess portions 113a on the flat-plate copper wire 133 can be performed as described above, a general-purpose flat-plate copper wire 133 may be used as the flat-plate copper wire 133. Thus, the degree of freedom in selection of the flat-plate copper wire 133 is high.

Alternatively, the solder 121 may be applied to the surface of the light-receiving-surface-side lead wire 113, which is not covered with the solder 121, in the placement process of the light-receiving-surface-side lead wire 113, and then the light-receiving-surface-side lead wire 113 may be placed on the light-receiving-surface bus electrode 104. Alternatively, the solder 121 may be applied to the upper surface 104c of the light-receiving-surface bus electrode 104 in the placement process of the light-receiving-surface-side lead wire 113, and then the light-receiving-surface-side lead wire 113, which is not covered with the solder 121, may be placed on the light-receiving-surface bus electrode 104.

Subsequently, the light-receiving-surface-side lead wires 113 and the rear-surface-side lead wires 114 are partially or along the entire lengths, pressed onto the solar cell 100 side while the light-receiving-surface-side lead wires 113 and the rear-surface-side lead wires 114 are heated. Since the surfaces of the light-receiving-surface-side lead wires 113 and the rear-surface-side lead wires 114 are covered with the solder 121, the solder 121 on the surfaces melt due to the heating. By pressing the light-receiving-surface-side lead wires 113 and the rear-surface-side lead wires 114 in this state, the light-receiving-surface-side lead wires 113 are soldered to the light-receiving-surface bus electrodes 104 and the rear-surface-side lead wires 114 are soldered to the rear-surface bus electrodes 105.

At this point in time, as illustrated in FIG. 17, the light-receiving-surface-side lead wire 113 is attached through the solder 121 to the light-receiving-surface bus electrode 104 with the protrusion portions 104a of the light-receiving-surface bus electrode 104 accommodated in the recess portions 113a of the light-receiving-surface-side lead wire 113. That is, the protrusion portions 104a of the light-receiving-surface bus electrode 104 are attached through the solder 121 to the recess portions 113a in the lower surface 113c of the light-receiving-surface-side lead wire 113. Additionally, the flat surfaces 104b of the upper surface 104c of the light-receiving-surface bus electrode 104 are attached through the solder 121 to the flat surfaces 113b of the lower surface 113c of the light-receiving-surface-side lead wire 113.

The light-receiving-surface-side lead wire 113 can be prevented from shifting in position in the longitudinal direction of the light-receiving-surface bus electrode 104 during the interconnection of the light-receiving-surface bus electrode 104 and the light-receiving-surface-side lead wire 113, by the placement on the light-receiving-surface bus electrode 104 with the protrusion portions 104a of the light-receiving-surface bus electrode 104 accommodated in the recess portions 113a of the light-receiving-surface-side lead wire 113 and by the attachment to the light-receiving-surface bus electrode 104 using the solder 121. In this manner, the light-receiving-surface-side lead wire 113 can be attached to the light-receiving-surface bus electrode 104 in a desired position; thus, the light-receiving-surface-side lead wires 113 can be attached with high position accuracy.

Subsequently, the first solar cell 100A, which is the first solar cell 100, and the second solar cell 100B, which is the second solar cell 100, are arranged in a connection direction. Then, the extension portions 113e of the light-receiving-surface-side lead wires 113 on the first solar cell 100A are brought to the rear surface side of the second solar cell 100B and placed on end portions of the rear-surface-side lead wires 114. The first solar cell 100A and the second solar cell 100B are then pressed while heated, so that the extension portions 113e of the light-receiving-surface-side lead wires 113 are soldered to the end portions of the rear-surface-side lead wires 114 of the second solar cell 100B. In this manner, the plurality of solar cells 100 is electrically connected in series, and thereby the solar cell array 30 is fabricated. Connecting the light-receiving-surface-side lead wires 113 and the rear-surface-side lead wires 114 to the solar cell 100 and connecting the light-receiving-surface-side lead wires 113 to the rear-surface-side lead wires 114 may be performed at the same time during an identical process.

Subsequently, the solar cell array 30 is placed in step S30 on the rear-surface covering material 112 with the resin 115b therebetween in accordance with the placement of the components of the solar module 10 illustrated in FIG. 19. The front-surface covering material 111 is placed on the solar cell array 30 with resin 115a therebetween to fabricate a stacked body including the components of the solar module 10.

Subsequently, laminating is performed in step S40 in which the stacked body is hot-pressed in a vacuum. In this laminating, the components of the stacked body are laminated to be integrated and form the solar panel 1. Then, the frame member 20 illustrated in FIG. 1 is mounted to a perimeter portion of the solar panel 1.

In FIGS. 12 to 15, the placement spacing D2 of the recess portions 113a in the lower surface 113c of the light-receiving-surface-side lead wire 113 is equal to the placement spacing D1 of the light-receiving-surface grid electrodes. The placement spacing D2 of the recess portions 113a may be a spacing that is “1/n (where n is an integer equal to or greater than 2)” of the placement spacing D1, as illustrated in FIG. 21. FIG. 21 is a sectional view of an important portion, illustrating another light-receiving-surface-side lead wire 141 according to the first embodiment of the present invention and corresponding to FIG. 14.

The placement spacing D2 of the recess portions 113a in the other light-receiving-surface-side lead wire 141 is a spacing that is ½ of the placement spacing D1 of the light-receiving-surface grid electrodes 103, that is, a spacing that is ½ of the placement spacing D2 of the recess portions 113a in the light-receiving-surface-side lead wire 113 illustrated in FIG. 14. The same effects as those of the light-receiving-surface-side lead wire 113 described above can be produced also in this case.

Additionally, the other light-receiving-surface-side lead wire 141 can be used also in the solar module 10 including the light-receiving-surface bus electrodes 104 having the protrusion portions 104a whose placement spacing is a spacing that is ½ of the placement spacing D1 illustrated in FIG. 10, thereby achieving a common light-receiving-surface-side lead wire. This is similarly the case when n, which is a positive integer, is equal to or greater than three.

Additionally, if the attachment position of the light-receiving-surface-side lead wire 113 with respect to the light-receiving-surface bus electrode 104 is shifted from a desired set position in the longitudinal direction of the light-receiving-surface bus electrode 104 by about ½ of the placement spacing D1 of the light-receiving-surface grid electrodes, the characteristics of the solar module 10 are not adversely affected. That is, if the attachment position of the light-receiving-surface-side lead wire 113 with respect to the light-receiving-surface bus electrode 104 is shifted from a desired set position in the longitudinal direction of the light-receiving-surface bus electrode 104 by a distance corresponding to the placement spacing D2, there is no problem.

When the other light-receiving-surface-side lead wire 141 is used, the accuracy with which the recess portions 113a are aligned with the protrusion portions 104a can be ½ of that employed when the light-receiving-surface-side lead wire 113 is used. Accordingly, when the other light-receiving-surface-side lead wire 141 is used, the load on the alignment of the light-receiving-surface-side lead wire 113 with the light-receiving-surface bus electrode 104 can be reduced.

Although the light-receiving-surface-side lead wire 113 and the light-receiving-surface bus electrode 104 are connected together using solder in the description above, the light-receiving-surface-side lead wire 113 and the light-receiving-surface bus electrode 104 may be connected together using a conductive adhesive agent.

Additionally, if the structures of the rear-surface-side electrode in the solar module 10 are placed in the same manner as those of the light-receiving-surface-side electrode, the connecting structure of the light-receiving-surface bus electrodes 104 and the light-receiving-surface-side lead wires 113 described above may be used for the rear-surface-side electrodes and the rear-surface-side lead wires 114. The effects in the embodiment described above can be produced also in this case.

As described above, in the solar module 10 according to the first embodiment, the protrusion portions 104a of each of the light-receiving-surface bus electrodes 104 are through the solder 121 attached to the recess portions 113a in the lower surface 113c of the corresponding one of the light-receiving-surface-side lead wires 113 with no gap therebetween. Additionally, in the solar module 10, the flat surfaces 104b of the upper surface 104c of each of the light-receiving-surface bus electrodes 104 are attached through the solder 121 to the flat surfaces 113b of the lower surface 113c of the corresponding one of the light-receiving-surface-side lead wires 113 with no gap therebetween. In this manner, the solar module 10 maintains a large area for connecting the light-receiving-surface bus electrodes 104 and the light-receiving-surface-side lead wires 113 together and thereby provides high attachment strength between the light-receiving-surface bus electrodes 104 and the light-receiving-surface-side lead wires 113. Accordingly, the solar module 10 according to the first embodiment achieves a high quality solar module in which the light-receiving-surface bus electrodes 104 and the light-receiving-surface-side lead wires 113 are attached together with high long-term reliability and the light-receiving-surface bus electrodes 104 and the light-receiving-surface-side lead wires 113 are electrically attached together with high long-term reliability.

### Second Embodiment

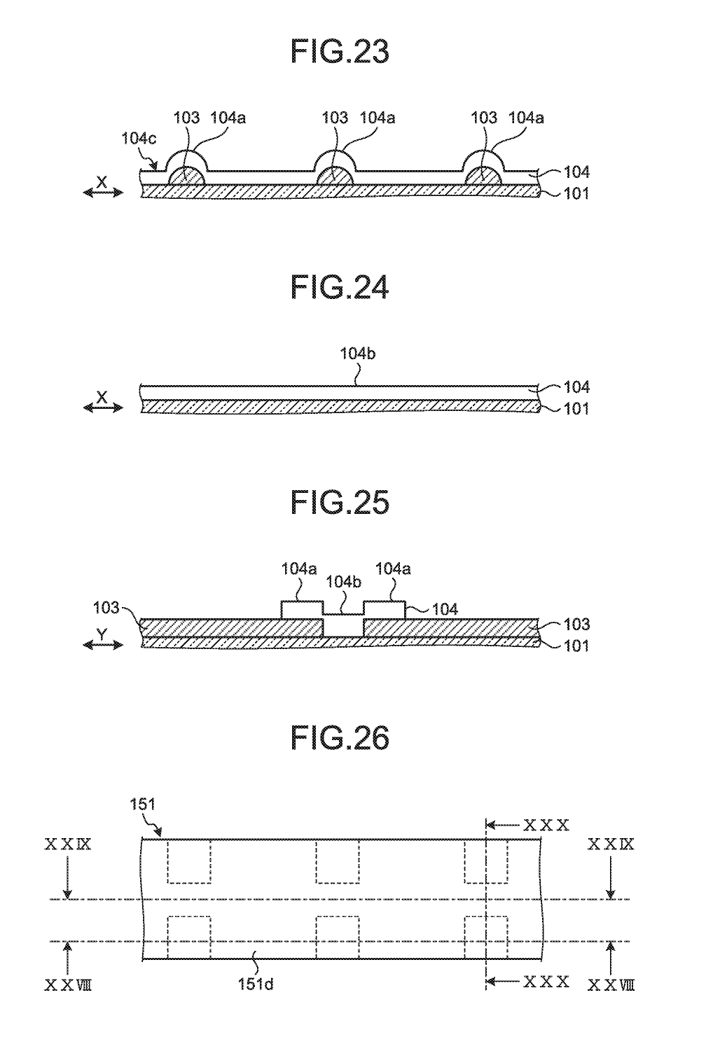

FIG. 22 is a top view of an important portion of a solar cell according to a second embodiment of the present invention, illustrating a connection portion of the light-receiving-surface grid electrode 103 and the light-receiving-surface bus electrode 104. FIG. 23 is a sectional view of an important portion of the solar cell according to the second embodiment of the present invention taken along line XXIII-XXIII in FIG. 22, illustrating the connection portion of the light-receiving-surface grid electrode 103 and the light-receiving-surface bus electrode 104. FIG. 24 is a sectional view of an important portion of the solar cell according to the second embodiment of the present invention taken along line XXIV-XXIV in FIG. 22, illustrating the light-receiving-surface bus electrode 104. FIG. 25 is a sectional view of an important portion of the solar cell according to the second embodiment of the present invention taken along line XXV-XXV in FIG. 22, illustrating the connection portion of the light-receiving-surface grid electrode 103 and the light-receiving-surface bus electrode 104. Components of the same types as those illustrated in the first embodiment are described using the same symbols in some cases.

As illustrated in FIG. 22, in the solar cell according to the second embodiment, each of the light-receiving-surface grid electrodes 103 is divided in a center region in the longitudinal direction of the light-receiving-surface grid electrodes 103, which is the Y direction, in a region underneath the light-receiving-surface bus electrode 104. The solar module according to the second embodiment has the same structure as the solar module 10 according to the first embodiment except for the light-receiving-surface bus electrodes 104 that are formed over regions in which the light-receiving-surface grid electrodes 103 are divided.

As illustrated in FIG. 23, the upper surface 104c of the light-receiving-surface bus electrode 104 has the flat surface 104b and the protrusion portion 104a, which is elevated due to the light-receiving-surface bus electrode 104 being placed on the light-receiving-surface grid electrode 103 to protrude from the upper surface 104c. Note that, as illustrated in FIGS. 22 to 25, the protrusion portion 104a is not continuous along the entire width in the width direction of the light-receiving-surface bus electrode 104 but divided at the same position and in the same shape as the light-receiving-surface grid electrode 103 into a shape that corresponds to that of the light-receiving-surface grid electrode 103 in the width direction of the light-receiving-surface bus electrode 104, which is the Y direction. That is, protrusion portions 104a are formed on the light-receiving-surface grid electrodes 103 on only both end sides in the width direction.

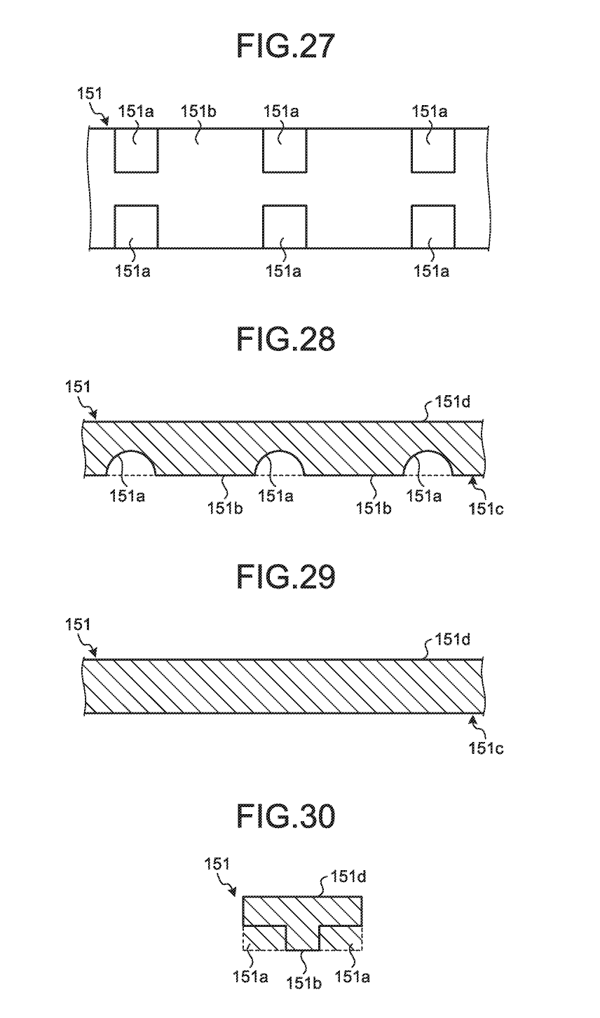

FIG. 26 is a top view of an important portion of a light-receiving-surface-side lead wire 151 according to the second embodiment of the present invention. FIG. 27 is a bottom view of an important portion of the light-receiving-surface-side lead wire 151 according to the second embodiment of the present invention. FIG. 28 is a sectional view of an important portion of the light-receiving-surface-side lead wire 151 according to the second embodiment of the present invention, taken along line XXVIII-XXVIII in FIG. 26. FIG. 29 is a sectional view of an important portion of the light-receiving-surface-side lead wire 151 according to the second embodiment of the present invention, taken along line XXIX-XXIX in FIG. 26. FIG. 30 is a sectional view of an important portion of the light-receiving-surface-side lead wire 151 according to the second embodiment of the present invention, taken along line XXX-XXX in FIG. 26.

As illustrated in FIGS. 26 to 30, the light-receiving-surface-side lead wire 151 according to the second embodiment, which is connected to the light-receiving-surface bus electrode 104 configured as described above in the solar cell according to the second embodiment, has a lower surface 151c that is an attachment surface to the light-receiving-surface bus electrode 104, and the lower surface 151c has a recess portion 151a that has a shape corresponding to that of the protrusion portion 104a and extends in the width direction of the light-receiving-surface-side lead wire 151, and a flat surface 151b. That is, the light-receiving-surface-side lead wire 151 has recess portions 151a that are formed in the lower surface 151c and have shapes corresponding to the uneven shape of the light-receiving-surface bus electrode 104. As illustrated in FIG. 27, the recess portion 151a is not continuous along the entire width in the width direction of the light-receiving-surface-side lead wire 151 but divided in the width direction of the light-receiving-surface-side lead wire 151 at a position and in a shape corresponding to those of the protrusion portion 104a of the light-receiving-surface bus electrode 104 in the placement position of the protrusion portion 104a.

Flat surfaces 151b correspond to all regions of the lower surface 151c of the light-receiving-surface-side lead wire 151 where the recess portions 151a are not formed. The placement spacing D2 of the recess portions 151a is equal to the placement spacing D1. The light-receiving-surface-side lead wire 151 has an upper surface 151d that is a flat surface and opposite from the lower surface 151c.

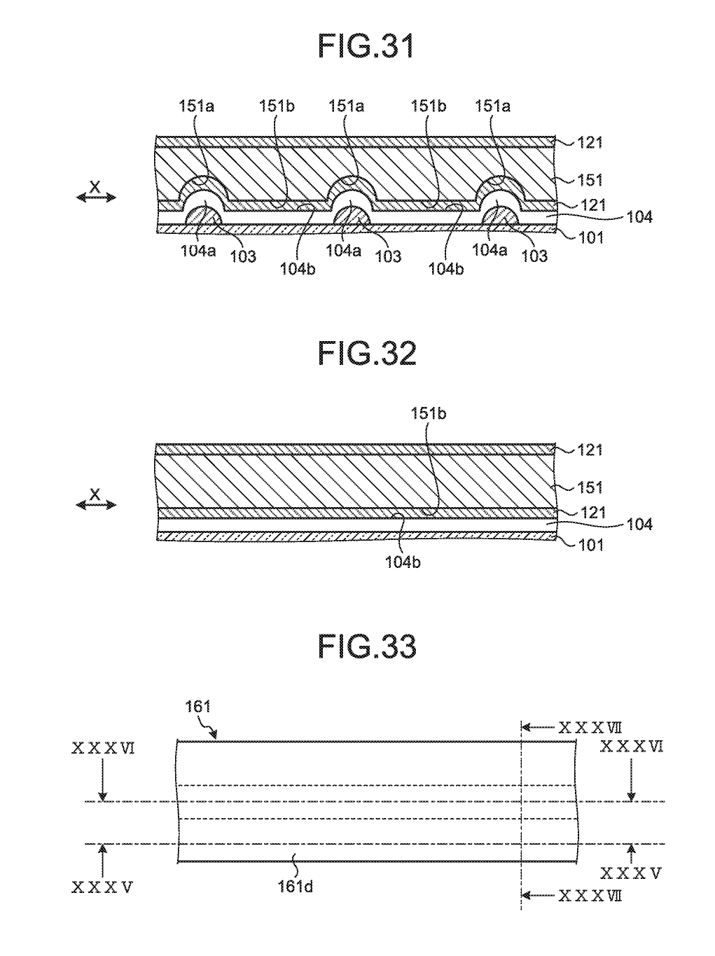

FIG. 31 is a sectional view of an important portion of the light-receiving-surface-side lead wire 151 according to the second embodiment of the present invention, illustrating the light-receiving-surface-side lead wire 151 attached to the light-receiving-surface bus electrode 104 of the solar cell according to the second embodiment, taken along the longitudinal direction of the light-receiving-surface-side lead wire 151 at a position in which the recess portion 151a is formed. FIG. 32 is a sectional view of an important portion of the light-receiving-surface-side lead wire 151 according to the second embodiment of the present invention, illustrating the light-receiving-surface-side lead wire 151 attached to the light-receiving-surface bus electrode 104 of the solar cell according to the second embodiment, taken along the longitudinal direction of the light-receiving-surface-side lead wire 151 at a position in which the recess portion 151a is not formed.

As illustrated in FIG. 31, the light-receiving-surface-side lead wire 151 is placed on the light-receiving-surface bus electrode 104 and attached through the solder 121 to the light-receiving-surface bus electrode 104 with the protrusion portions 104a of the light-receiving-surface bus electrode 104 accommodated in the recess portions 151a of the light-receiving-surface-side lead wire 151. That is, the protrusion portions 104a of the light-receiving-surface bus electrode 104 are attached through the solder 121 to the recess portions 151a with no gap therebetween, with the protrusion portions 104a fitted in the recess portions 151a in the lower surface 151c of the light-receiving-surface-side lead wire 151. The flat surfaces 104b of the light-receiving-surface bus electrode 104 are also attached though the solder 121 to the flat surfaces 151b of the lower surface 151c of the light-receiving-surface-side lead wire 151 with no gap therebetween. The flat surfaces 104b in regions between the protrusion portions 104a in the width direction of the light-receiving-surface bus electrode 104 are also attached through the solder 121 to the flat surfaces 151b of the lower surface 151c of the light-receiving-surface-side lead wire 151 with no gap therebetween.

In this manner, the solar module according to the second embodiment maintains a large area for connecting the light-receiving-surface bus electrodes 104 and the light-receiving-surface-side lead wires 151 together and thereby provides high attachment strength between the light-receiving-surface bus electrodes 104 and the light-receiving-surface-side lead wires 151, as in the case with the solar module 10 according to the first embodiment. Accordingly, the solar module according to the second embodiment achieves a high quality solar module in which the light-receiving-surface bus electrodes 104 and the light-receiving-surface-side lead wires 151 are attached together with high long-term reliability and the light-receiving-surface bus electrodes 104 and the light-receiving-surface-side lead wires 151 are electrically attached together with high long-term reliability.

In the solar module according to the second embodiment, the separate protrusion portions 104a of each of the light-receiving-surface bus electrodes 104 are accommodated in and attached to the recess portions 151a of the corresponding one of the light-receiving-surface-side lead wires 151. The light-receiving-surface-side lead wire 151 is thus prevented from shifting in position in the width direction of the light-receiving-surface bus electrode 104. In this manner, the light-receiving-surface-side lead wire 151 can be attached with high positional accuracy, and thereby a shadow loss resulting from a shift in position of the light-receiving-surface-side lead wire 151 can be prevented.

### Third Embodiment

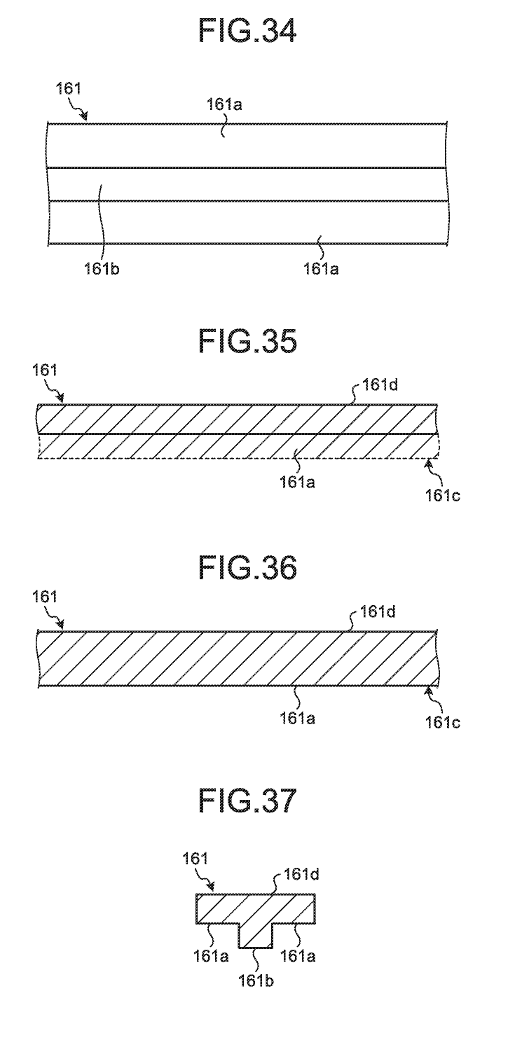

FIG. 33 is a top view of an important portion of a light-receiving-surface-side lead wire 161 according to a third embodiment of the present invention. FIG. 34 is a bottom view of an important portion of the light-receiving-surface-side lead wire 161 according to the third embodiment of the present invention. FIG. 35 is a sectional view of an important portion of the light-receiving-surface-side lead wire 161 according to the third embodiment of the present invention, taken along line XXXV-XXXV in FIG. 33. FIG. 36 is a sectional view of an important portion of the light-receiving-surface-side lead wire 161 according to the third embodiment of the present invention, taken along line XXXVI-XXXVI in FIG. 33. FIG. 37 is a sectional view of an important portion of the light-receiving-surface-side lead wire 161 according to the third embodiment of the present invention, taken along line XXXVII-XXXVII in FIG. 33.

When a connection portion of the light-receiving-surface grid electrode 103 and the light-receiving-surface bus electrode 104 has a structure illustrated in FIGS. 22 to 25, the light-receiving-surface-side lead wire 161 illustrated in FIGS. 33 to 37 may be connected to the light-receiving-surface bus electrode 104. A solar module according to the third embodiment has the same structure as the solar module according to the second embodiment except for light-receiving-surface-side lead wires 161 that are used in place of the light-receiving-surface-side lead wires 151.

The light-receiving-surface-side lead wire 161 according to the third embodiment has a lower surface 161c that is an attachment surface to the light-receiving-surface bus electrode 104, and the lower surface 161c has a groove-like recess portion 161a that has a widthwise or lateral shape corresponding to that of the protrusion portion 104a and extends in the longitudinal direction of the light-receiving-surface-side lead wire 161, and a flat surface 161b. That is, the light-receiving-surface-side lead wire 161 has recess portions 161a that are formed in the lower surface 161c and have widthwise or lateral shapes corresponding to the uneven shape of the light-receiving-surface bus electrode 104. The recess portion 161a is not continuous along the entire width in the width direction of the light-receiving-surface-side lead wire 161 but divided in the width direction of the light-receiving-surface-side lead wire 161 at a position and in a shape corresponding to those of the protrusion portion 104a of the light-receiving-surface bus electrode 104 in the placement position of the protrusion portion 104a. That is, the recess portions 161a are formed on only both end sides in the width direction of the light-receiving-surface-side lead wires 161.

The flat surface 161b corresponds to all the region of the lower surface 161c of the light-receiving-surface-side lead wire 161 where the recess portions 161a are not formed, and corresponds to a region between the recess portions 161a in the width direction. The light-receiving-surface-side lead wire 161 has an upper surface 161d that is a flat surface and opposite from the lower surface 161c.

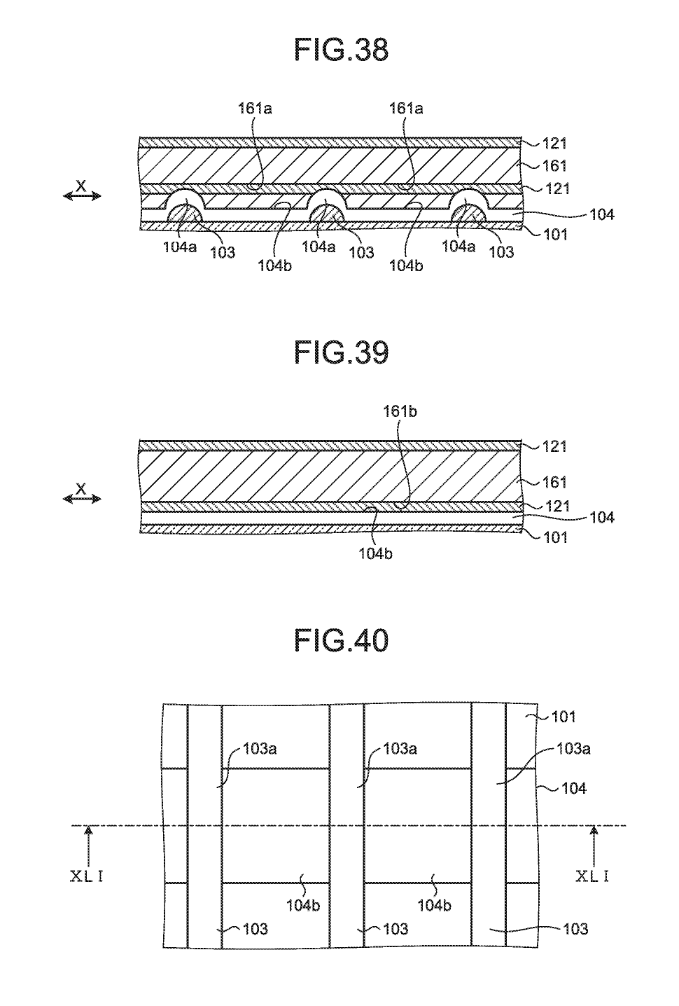

FIG. 38 is a sectional view of an important portion of the light-receiving-surface-side lead wire 161 according to the third embodiment of the present invention, illustrating the light-receiving-surface-side lead wire 161 attached to the light-receiving-surface bus electrode 104 illustrated in FIGS. 22 to 25, taken along the longitudinal direction of the light-receiving-surface-side lead wire 161 at a position in which the recess portion 161a is formed. FIG. 39 is a sectional view of an important portion of the light-receiving-surface-side lead wire 161 according to the third embodiment of the present invention, illustrating the light-receiving-surface-side lead wire 161 attached to the light-receiving-surface bus electrode 104 illustrated in FIGS. 22 to 25, taken along the longitudinal direction of the light-receiving-surface-side lead wire 161 at a position in which the recess portion 161a is not formed.

As illustrated in FIG. 38, the light-receiving-surface-side lead wire 161 is placed on the light-receiving-surface bus electrode 104 and attached through the solder 121 to the light-receiving-surface bus electrode 104 with the protrusion portions 104a of the light-receiving-surface bus electrode 104 accommodated in the recess portions 161a of the light-receiving-surface-side lead wire 161. That is, upper portions of the protrusion portions 104a of the light-receiving-surface bus electrode 104 are attached through the solder 121 to bottom surfaces of the recess portions 161a in the lower surface 161c of the light-receiving-surface-side lead wire 161. The flat surfaces 104b in regions between the protrusion portions 104a in the width direction of the light-receiving-surface bus electrode 104 are also attached through the solder 121 to the flat surface 161b of the lower surface 161c of the light-receiving-surface-side lead wire 161 with no gap therebetween.

In this manner, the solar module according to the third embodiment maintains an area that is smaller than that of the solar module according to the second embodiment but is still large for connecting the light-receiving-surface bus electrodes 104 and the light-receiving-surface-side lead wires 161 together and thereby provides high attachment strength between the light-receiving-surface bus electrodes 104 and the light-receiving-surface-side lead wires 161. Accordingly, the solar module according to the third embodiment achieves a high quality solar module in which the light-receiving-surface bus electrodes 104 and the light-receiving-surface-side lead wires 161 are attached together with high long-term reliability and the light-receiving-surface bus electrodes 104 and the light-receiving-surface-side lead wires 161 are electrically attached together with high long-term reliability.

In the solar module according to the third embodiment, the divided protrusion portions 104a of each of the light-receiving-surface bus electrodes 104 are accommodated in and attached to the recess portions 161a of the corresponding one of the light-receiving-surface-side lead wires 161. The light-receiving-surface-side lead wire 161 is thus prevented from shifting in position in the width direction of the light-receiving-surface bus electrodes 104. In this manner, the light-receiving-surface-side lead wire 161 can be attached with high positional accuracy, and thereby a shadow loss resulting from a shift in position of the light-receiving-surface-side lead wire 161 can be prevented.

### Fourth Embodiment

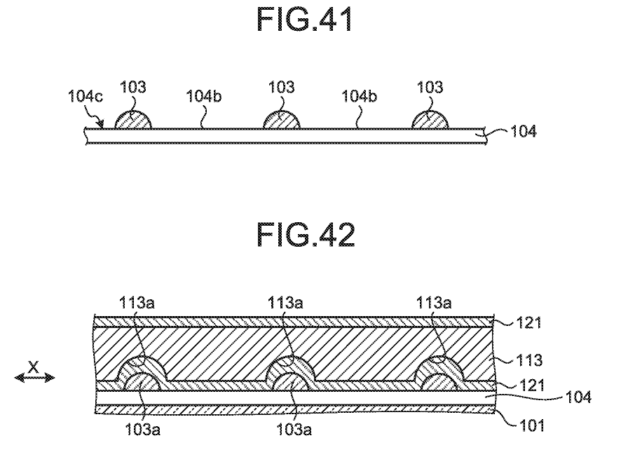

Although the protrusion portions are formed by placing the light-receiving-surface bus electrode 104 on the light-receiving-surface grid electrodes 103 in the foregoing embodiments described above, similar effects as those described above can be produced by using the light-receiving-surface-side lead wire according to the foregoing embodiments in a case where the protrusion portions are formed by placing the light-receiving-surface grid electrodes 103 on the light-receiving-surface bus electrode 104. As an example, a connection portion of the light-receiving-surface grid electrodes 103 and the light-receiving-surface bus electrode 104 in a case where the first embodiment is modified to provide the light-receiving-surface-side electrode formed by placing the light-receiving-surface grid electrodes 103 on the light-receiving-surface bus electrode 104 is illustrated in FIGS. 40 and 41.

FIG. 40 is a top view of an important portion of a solar cell according to a fourth embodiment of the present invention, illustrating a connection portion of the light-receiving-surface grid electrode 103 and the light-receiving-surface bus electrode 104. FIG. 41 is a sectional view of an important portion of the solar cell according to the fourth embodiment of the present invention taken along line XLI-XLI in FIG. 40, illustrating the connection portion of the light-receiving-surface grid electrode 103 and the light-receiving-surface bus electrode 104.

As illustrated in FIGS. 40 and 41, an elevated protrusion portion 103a that protrudes from the upper surface 104c of the light-receiving-surface bus electrode 104 is formed in the width direction of the light-receiving-surface bus electrode 104 with the light-receiving-surface grid electrode 103 placed on the light-receiving-surface bus electrode 104. The protrusion portion 103a corresponds to the protrusion portion 104a in the first embodiment.

FIG. 42 is a sectional view of an important portion of the light-receiving-surface bus electrode 104 according to the fourth embodiment of the present invention, illustrating the light-receiving-surface-side lead wire 113 attached to the light-receiving-surface bus electrode 104. As illustrated in FIG. 42, the light-receiving-surface-side lead wire 113 is placed on the light-receiving-surface bus electrode 104 and attached through the solder 121 to the light-receiving-surface bus electrode 104 with protrusion portions 103a of the light-receiving-surface grid electrodes 103 accommodated in the recess portions 113a of the light-receiving-surface-side lead wire 113. Similar effects as those of the first embodiment described above can be produced also in this case. Although the positions and shapes of the protrusion portions 103a on the light-receiving-surface bus electrode 104 are substantially the same with those of the protrusion portions 104a, the external dimensions of the protrusion portions 103a are somewhat smaller than those of the protrusion portions 104a and hence the dimensions of the recess portions 113a in the light-receiving-surface-side lead wire 113 may be somewhat reduced in accordance with the dimensions of the protrusion portions 103a.

Techniques in which protrusions and recesses are formed in a lead wire are described in literatures such as Japanese Patent Application Laid-open No. 2004-200517, Japanese Patent Application Laid-open No. 2006-059991, and WO/2012/111108. In these literatures, lead wires are described each of which has protrusions and recesses formed on the front and rear surfaces over the entire lead wire, and the protrusions and the recesses are identical in shape on the front and rear surfaces. Additionally, the protrusions and the recesses included in such lead wires described in these literatures are formed in no relation with the shape of grid electrodes. In the techniques described in these literatures, the lead wire is not placed with a protrusion portion of the bus electrode accommodated in a recess portion of the lead wire placed in its lower surface, which is the attachment surface to the electrode. Thus, the techniques described in the literatures described above do not produces operational advantages described in the foregoing embodiments.

Note that the configurations described in the foregoing embodiments are examples of the present invention; combining the present invention with other publicly known techniques is possible, and partial omissions and modifications are possible without departing from the spirit of the present invention.

### REFERENCE SIGNS LIST

1 solar panel; 10 solar module; 11 lead wire; 20 frame member; 30 solar cell array; 100 solar cell; 100A first solar cell; 100B second solar cell; 101 p-type monocrystalline silicon substrate; 102 rear-surface collecting electrode; 103 light-receiving-surface grid electrode; 103a, 104a protrusion portion; 104 light-receiving-surface bus electrode; 104b flat surface; 104c, 113d, 151d, 161d top surface; 105 rear-surface bus electrode; 111 front-surface covering material; 112 rear-surface covering material; 113, 151, 161 light-receiving-surface-side lead wire; 113a, 151a, 161a recess portion; 113b, 151b, 161b flat surface; 113c, 151c, 161c lower surface; 113e extension portion; 114 rear-surface-side lead wire; 115, 115a, 115b resin; 116 cell arrangement layer; 121 solder; 131 upper roller; 132 lower roller; 132a protrusion; 133 flat-plate copper wire; 141 another light-receiving-surface-side lead wire; D1 light-receiving-surface-grid-electrode placement spacing; D2 recess-portion placement spacing.

1. A solar module comprising:
a plurality of grid electrodes extending in a predefined direction and placed in parallel with each other on a one surface side of a semiconductor substrate having a photoelectric conversion portion;
a bus electrode extending in a direction intersecting with the predefined direction on the one surface side of the semiconductor substrate; and
a lead wire extending in the direction intersecting with the predefined direction and placed on and attached to the bus electrode,
wherein the bus electrode has a protrusion portion on an upper surface thereof in an intersection region where the bus electrode intersects with each of the grid electrodes, the protrusion portion protruding from the upper surface of the bus electrode and having a shape corresponding to a shape of each of the grid electrodes with the bus electrode and each of grid electrodes overlapping,
the lead wire has a copper wire and solder covering the copper wire, the copper wire having a recess portion formed in a lower surface thereof, the recess portion being capable of accommodating the protrusion portion therein, the copper wire having an upper surface that is a flat surface and opposite from the lower surface, the lower surface being an attachment surface to the bus electrode, and
a bottom surface of the recess portion and an upper portion of the protrusion portion are attached together with the protrusion portion accommodated in the recess portion, and the lower surface is attached to the upper surface of the bus electrode.

2. The solar module according to claim 1, wherein the bus electrode and the lead wire are attached together through solder or a conductive adhesive agent.

3. The solar module according to claim 2, wherein the recess portion has a shape corresponding to a shape of the protrusion portion, the recess portion being plural in number, the plural recess portions being placed in the direction intersecting with the predefined direction, and
the protrusion portion and a corresponding one of the recess portions are attached together with the protrusion portion fitted in the corresponding recess portion, and the lower surface of the lead wire is attached to the upper surface of the bus electrode.

4. The solar module according to claim 3, wherein the protrusion portion of the bus electrode is continuously placed in the predefined direction.

5. The solar module according to claim 3, wherein the protrusion portion of the bus electrode is divided into two in the predefined direction.

6. The solar module according to claim 3, wherein a placement spacing of the recess portions in the direction intersecting with the predefined direction is identical with a predefined placement spacing of the plurality of grid electrodes.

7. The solar module according to claim 3, wherein, when n is an integer equal to or greater than two, the placement spacing of the recess portions in the direction intersecting with the predefined direction is 1/n of the predefined placement spacing of the plurality of grid electrodes.

8. A method for manufacturing a solar module, the method comprising:
printing and forming a plurality of grid electrodes extending in a predefined direction and placed in parallel with each other on a one surface side of a semiconductor substrate having a photoelectric conversion portion;
printing and forming a bus electrode extending in a direction intersecting with the predefined direction on the one surface side of the semiconductor substrate; and
attaching a lead wire to the bus electrode with the lead wire placed on the bus electrode, the lead wire extending in the direction intersecting with the predefined direction, the lead wire having an upper surface that is a flat surface and opposite from a lower surface of the lead wire, the lower surface of the lead wire being an attachment surface to the bus electrode, the lead wire having a recess portion in the lower surface,
wherein performing the printing and formation of the grid electrodes and the printing and formation of the bus electrode forms a protrusion portion protruding from an upper surface of the bus electrode and having a shape that corresponds to a shape of each of the grid electrodes with the bus electrode and each of the grid electrodes overlapping in an intersection region between the bus electrode intersects with each of the grid electrodes, and
during the attachment of the lead wire to the bus electrode, a bottom surface of the recess portion is attached to an upper portion of the protrusion portion with the protrusion portion accommodated in the recess portion, and the lower surface of the lead wire is attached to the upper surface of the bus electrode.

9. The method for manufacturing the solar module according to claim 8, wherein the bus electrode and the lead wire are attached together through solder or a conductive adhesive agent.

10. The method for manufacturing the solar module according to claim 9, wherein the recess portion has a shape corresponding to a shape of the protrusion portion, the recess portion being plural in number, the plural recess portions being placed in the direction intersecting with the predefined direction, and
the protrusion portion and a corresponding one of the recess portions are attached together with the protrusion portion fitted in the corresponding recess portion, and the lower surface of the lead wire and the upper surface of the bus electrode are attached together.

11. The method for manufacturing the solar module according to claim 10, wherein the protrusion portion of the bus electrode is continuously placed in the predefined direction.

12. The method for manufacturing the solar module according to claim 10, wherein the protrusion portion of the bus electrode is divided into two in the predefined direction.

13. The method for manufacturing the solar module according to claim 10, wherein a placement spacing of the recess portions in the direction intersecting with the predefined direction is identical with a predefined placement spacing of the plurality of grid electrodes.

14. The method for manufacturing the solar module according to claim 10, when n is an integer equal to or greater than two, the placement spacing of the recess portions in the direction intersecting with the predefined direction is 1/n of the predefined placement spacing of the plurality of grid electrodes.

15. A lead wire to be attached to a solar cell including a bus electrode having a protrusion portion on an upper surface thereof, the protrusion portion protruding in correspondence to a shape of a grid electrode, wherein
the lead wire has:
an upper surface that is a flat surface and opposite from a lower surface of the lead wire, the lower surface being an attachment surface to the bus electrode; and
a recess portion in the lower surface, the recess portion being capable of accommodating the protrusion portion therein, and
a bottom surface of the recess portion and an upper portion of the protrusion portion are attached together with the protrusion portion accommodated in the recess portion, and the lower surface is attached to the upper surface of the bus electrode.
